(19) United States
(12) Patent Application Publication
(10) Pub. No.: US 2026/0011382 A1
(43) Pub. Date: Jan. 8, 2026

(54) MEMORY SYSTEM AND METHOD FOR CONTROLLING NON-VOLATILE MEMORY

(71) Applicant: Kioxia Corporation, Tokyo (JP)

(72) Inventors: Marie Takada, Yokohama Kanagawa (JP); Masanobu Shirakawa, Chigasaki Kanagawa (JP)

(73) Assignee: Kioxia Corporation, Tokyo (JP)

(21) Appl. No.: 19/079,002

(22) Filed: Mar. 13, 2025

(30) Foreign Application Priority Data
Jul. 5, 2024 (JP) 2024-108972

(51) Int. Cl. G11C 16/34; G06F 12/02; G11C 11/56; G11C 16/04; G11C 16/10; G11C 16/26

(52) U.S. Cl. CPC G11C 16/3495; G06F 12/0246; G11C 11/5628; G11C 11/5642; G11C 11/5671; G11C 16/0483; G11C 16/10; G11C 16/26

(57) ABSTRACT

According to one embodiment, a memory system includes a memory chip including a plurality of memory cells each of which is capable of storing data corresponding to one of a plurality of states and a memory controller. The memory controller is configured to control a write operation and a read operation performed on the memory cells and calculate a shift amount of a read voltage in the read operation based on at least one of a plurality of first count values of write data corresponding to the plurality of states in the write operation and a second count value corresponding to the read voltage.

### CROSS-REFERENCE TO RELATED APPLICATIONS

This application is based upon and claims the benefit of priority from Japanese Patent Application No. 2024-108972, filed Jul. 5, 2024, the entire contents of which are incorporated herein by reference.

### FIELD

Embodiments described herein relate generally to a memory system and a method for controlling a non-volatile memory.

### BACKGROUND

As a memory system, a solid state drive (SSD) on which a non-volatile memory device such as a NAND flash memory is mounted is known.

### BRIEF DESCRIPTION OF THE DRAWINGS

FIG. 1 is a block diagram illustrating an example of an overall configuration of a data processing device including a memory system according to a first embodiment.

FIG. 2 is a block diagram of a memory chip included in the memory system according to the first embodiment.

FIG. 3 is a circuit diagram illustrating an example of a circuit configuration of a memory cell array included in the memory system according to the first embodiment.

FIG. 4 is a block diagram of a data register and a sense amplifier included in the memory system according to the first embodiment.

FIG. 5 illustrates a relationship among a threshold voltage distribution, data allocation, and a count value of the number of bits in a case where memory cell transistors are TLCs that can store 3-bit (8-value) data in the memory system according to the first embodiment.

FIG. 6 illustrates an example of a bit count management table included in the memory system according to the first embodiment.

FIG. 7 is a conceptual diagram illustrating a relationship between a count value Nvb and a count value (Ner+Na) corresponding to a read voltage VB in the memory system according to the first embodiment.

FIG. 8 is a conceptual diagram illustrating an example of a relationship between a difference between the count value Nvb and the count value (Ner+Na) and a shift amount in the memory system according to the first embodiment.

FIG. 9 is a flowchart illustrating an example of overall flow of a write operation in the memory system according to the first embodiment.

FIG. 10 illustrates an example of flow of write data in the memory chip included in the memory system according to the first embodiment.

FIG. 11 is a timing chart illustrating an example of a command sequence of a write operation in the memory system according to the first embodiment.

FIG. 12 illustrates an example of data allocation in a read operation of lower page data in the memory system according to the first embodiment.

FIG. 13 is a flowchart illustrating an example of overall flow of a bit count read operation of the lower page data in the memory system according to the first embodiment.

FIG. 14 illustrates an example of flow of the lower page data in a normal read operation in the memory system according to the first embodiment.

FIG. 15 illustrates an example of flow of the lower page data in the bit count read operation in the memory system according to the first embodiment.

FIG. 16 is a timing chart illustrating an example of a command sequence of the normal read operation of the lower page data in the memory system according to the first embodiment.

FIG. 17 is a timing chart illustrating an example of a command sequence of the bit count read operation of the lower page data in the memory system according to the first embodiment.

FIG. 18 is a flowchart illustrating an example in which the bit count read operation is applied to host read in the memory system according to the first embodiment.

FIG. 19 is a flowchart illustrating an example in which the bit count read operation is applied to patrol read in the memory system according to the first embodiment.

FIG. 20 is a flowchart illustrating an example of overall flow of a write operation in a memory system according to a second embodiment.

FIG. 21 illustrates an example of flow of write data in a memory chip included in the memory system according to the second embodiment.

FIG. 22 is a timing chart illustrating an example of a command sequence of a write operation in the memory system according to the second embodiment.

FIG. 23 is a timing chart illustrating a command sequence of a bit count read operation of lower page data in a memory system according to a first example of a third embodiment.

FIG. 24 is a timing chart illustrating a command sequence of a bit count read operation of lower page data in a memory system according to a second example of the third embodiment.

FIG. 25 is a flowchart illustrating an example in which a bit count read operation is applied to patrol read in a memory system according to a first example of a fourth embodiment.

FIG. 26 is a conceptual diagram illustrating data output from a memory chip to a memory controller in patrol read or host read in the memory system according to the first example of the fourth embodiment.

FIG. 27 illustrates a relationship among a threshold voltage distribution, data allocation, and a count value of the number of bits in a case where memory cell transistors are TLCs that can store 3-bit (8-value) data in a memory system according to a second example of the fourth embodiment.

FIG. 28 illustrates an example of a bit count management table included in the memory system according to the second example of the fourth embodiment.

FIG. 29 is a flowchart illustrating an example in which a bit count read operation is applied to patrol read in the memory system according to the second example of the fourth embodiment.

FIG. 30 illustrates a relationship among a threshold voltage distribution, data allocation, and a count value of the number of bits in a case where memory cell transistors are TLCs that can store 3-bit (8-value) data in a memory system according to a third example of the fourth embodiment.

FIG. 31 illustrates an example of a bit count management table included in the memory system according to the third example of the fourth embodiment.

FIG. 32 is a flowchart illustrating an example in which a bit count read operation is applied to patrol read in the memory system according to the third example of the fourth embodiment.

### DETAILED DESCRIPTION

In general, according to one embodiment, a memory system includes a memory chip including a plurality of memory cells each of which is capable of storing data corresponding to one of a plurality of states and a memory controller. The memory controller is configured to control a write operation and a read operation performed on the memory cells and calculate a shift amount of a read voltage in the read operation based on at least one of a plurality of first count values of write data corresponding to the plurality of states in the write operation and a second count value corresponding to the read voltage.

Hereinafter, embodiments will be described with reference to the drawings. In the following description, components having identical functions and configurations are given identical reference signs. In a case where a plurality of components having a common reference sign is distinguished, the common reference sign is given a suffix. Note that, in a case where a plurality of components does not need to be particularly distinguished, the plurality of components is given only a common reference sign, and is given no suffix. Here, the suffix is not limited to a subscript or a superscript, and examples thereof include a lower case alphabet added to the end of the reference sign, an index meaning a sequence, and the like.

### 1. FIRST EMBODIMENT

### 1.1 Configuration

### 1.1.1 Configuration of Data Processing Device

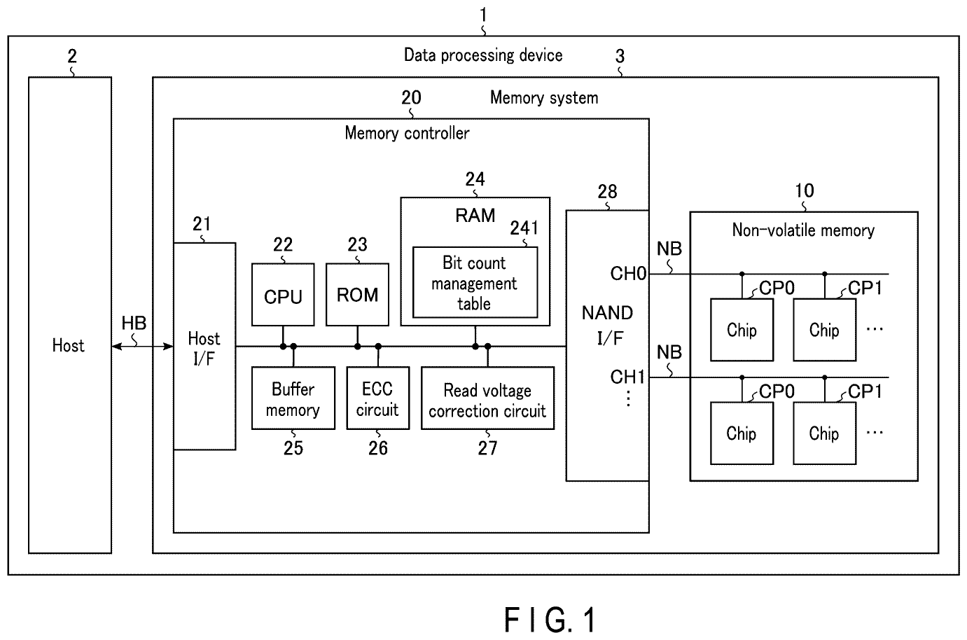

First, an example of a configuration of a data processing device 1 including a memory system will be described with reference to FIG. 1. FIG. 1 is a block diagram illustrating an example of an overall configuration of the data processing device 1.

As illustrated in FIG. 1, the data processing device 1 includes a host 2 and a memory system 3. The data processing device 1 may include a plurality of hosts 2 or a plurality of memory systems 3. In a case where the data processing device 1 includes a plurality of hosts 2 and a plurality of memory systems 3, a plurality of memory systems 3 may be coupled to one host 2. Furthermore, a plurality of hosts 2 may be coupled to one memory system 3.

The host 2 is an information processing device (computing device) that accesses the memory system 3. The host 2 controls the memory system 3. More specifically, for example, the host 2 requests (instructs) the memory system 3 to perform a write operation or a read operation of data (hereinafter, referred to as “user data”).

The memory system 3 is, for example, a solid state drive (SSD). The memory system 3 is coupled to the host 2 via a host bus HB. The type of the host bus depends on an application applied to the memory system 3. In a case where the memory system 3 is an SSD, the host bus conforms to, for example, the Peripheral Component Interconnect Express (PCIe™) standard. The memory system 3 executes processing based on a request signal received from the host 2 or a voluntary processing request.

### 1.1.2 Configuration of Memory System

Next, an example of a configuration of the memory system 3 will be described with reference to FIG. 1.

As illustrated in FIG. 1, the memory system 3 includes a non-volatile memory 10 and a memory controller 20.

The non-volatile memory 10 is a non-volatile storage medium (semiconductor memory device). The non-volatile memory 10 stores therein data received from the memory controller 20 in a non-volatile manner. Hereinafter, a case where the non-volatile memory 10 is a NAND flash memory will be described. Note that the non-volatile memory 10 may be a non-volatile storage medium other than the NAND flash memory.

The memory controller 20 is, for example, a system on a chip (SoC). The memory controller 20 instructs the non-volatile memory 10 to perform a read operation, a write operation, an erase operation, and the like based on a request (instruction) from the host 2. Furthermore, the memory controller 20 manages a memory region of the non-volatile memory 10.

Next, an example of an internal configuration of the non-volatile memory 10 will be described. The non-volatile memory 10 may include a plurality of memory chips CP (also simply referred to as “chips”). Each of the plurality of memory chips CP can operate independently. Note that the number of memory chips CP included in the non-volatile memory 10 may be arbitrary.

Each of the memory chips CP is, for example, a semiconductor chip on which a NAND flash memory is mounted. Note that the memory chip CP may be another non-volatile memory. The memory chip CP stores data in a non-volatile manner. The memory chip CP is coupled to the memory controller 20 via a NAND bus NB. Note that the number of the NAND buses NB and the number of the memory chips CP coupled to one NAND bus NB may be arbitrary.

Next, an example of an internal configuration of the memory controller 20 will be described. The memory controller 20 includes a host interface circuit (host I/F) 21, a central processing unit (CPU) 22, a read only memory (ROM) 23, a random access memory (RAM) 24, a buffer memory 25, an error check and correction (ECC) circuit 26, a read voltage correction circuit 27, and a NAND interface circuit (NAND I/F) 28. These circuits are coupled to each other by an internal bus of the memory controller 20. Note that the functions of the host interface circuit 21, the ECC circuit 26, the read voltage correction circuit 27, and the NAND interface circuit 28 may be realized by a dedicated circuit or may be realized by the CPU 22 executing firmware.

The host interface circuit 21 is an interface circuit coupled to the host 2 via the host bus HB. The host interface circuit 21 controls communication between the host 2 and the memory controller 20. The host interface circuit 21 transmits a request and user data received from the host 2 to the CPU 22 and the buffer memory 25, respectively. Furthermore, the host interface circuit 21 transmits user data in the buffer memory 25 to the host 2 under the control of the CPU 22.

The CPU 22 is a processor. The CPU 22 controls the whole memory controller 20. The CPU 22 controls the non-volatile memory 10. For example, the CPU 22 instructs the non-volatile memory 10 (memory chip CP) to perform the write operation, the read operation, and the erase operation based on a request from the host 2. In the following description, a case where the read operation that the memory system 3 causes the non-volatile memory 10 to execute based on a request from the host 2 is limited is referred to as “host read”.

Furthermore, the CPU 22 executes patrol processing. The patrol processing is executed regularly or irregularly in order to read data stored in the non-volatile memory 10 with a small number of fail bits (error bits). In the patrol processing, for example, a read operation is executed in the memory chip CP in a standby state, and a correction amount (hereinafter, also referred to as a “shift amount”) of a read voltage is updated based on a result of the read operation. Hereinafter, a case where the read operation in the patrol processing is limited is referred to as “patrol read”. The patrol processing is executed not by a request from the host 2 but by determination of the CPU 22. That is, the patrol read is executed by determination of the CPU 22 and is therefore different from the host read. The CPU 22 may execute the patrol read for each cell unit or may execute the patrol read for any cell unit. A cell unit is a set of a plurality of memory cell transistors collectively selected in a write operation or a read operation.

The ROM 23 is a non-volatile memory. For example, the ROM 23 is an electrically erasable programmable read-only memory (EEPROMTM). The ROM 23 is a non-transitory storage medium that stores firmware, programs, and the like. For example, the CPU 22 loads firmware from the ROM 23 to the RAM 24 and executes the firmware.

The RAM 24 is a volatile memory. The RAM 24 is a dynamic random access memory (DRAM), a static random access memory (SRAM), or the like. The RAM 24 is used as a work region of the CPU 22. Furthermore, the RAM 24 stores firmware for managing the non-volatile memory 10, various management tables, and the like. The RAM 24 stores, for example, a bit count management table 241. Note that information of the bit count management table 241 stored in the RAM 24 is irregularly non-volatilized. In other words, the information of the bit count management table 241 stored in the RAM 24 is irregularly stored in the non-volatile memory 10.

The bit count management table 241 is a table that manages information on a cell unit CU used to calculate the shift amounts of the read voltages and information on the shift amounts of the read voltages and expected values of the number of bits in the cell unit CU. For example, the number (count value) of memory cell transistors included in each state of write data is stored as the expected value of the number of bits. Note that the bit count management table 241 will be described later in detail. For example, in the read operation, the CPU 22 transmits a command set (hereinafter, also referred to as “Set Feature”) of parameter setting related to the shift amount of the read voltage and a command set of the read operation to the non-volatile memory 10 by referring to the bit count management table 241. The command set of the read operation includes an execution command of the read operation and an address. The non-volatile memory 10 shifts a default read voltage based on the shift amount of the read voltage.

The buffer memory 25 is a volatile semiconductor memory. The buffer memory 25 is a DRAM, an SRAM, or the like. The buffer memory 25 temporarily stores user data, write data, read data, and the like.

The ECC circuit 26 is a circuit that executes ECC processing. The ECC processing includes encoding and decoding of data. The encoding is an operation of generating a code word based on data. For example, the ECC circuit 26 generates an error correction code (hereinafter, also referred to as “parity”.) based on user data. Then, the ECC circuit 26 generates a code word, that is, write data by adding the parity to the user data. The decoding is an operation of performing error correction of data. The ECC circuit 26 decodes data read from the non-volatile memory 10.

The read voltage correction circuit 27 is a circuit that calculates a correction amount (shift amount) of the read voltage in the non-volatile memory 10 under the control of the CPU 22. For example, the read voltage correction circuit 27 calculates (counts) the number of bits (the number of memory cell transistors) for each state of the write data in the write operation. The read voltage correction circuit 27 stores the count value of the number of bits for each state of the write data in the bit count management table 241 as an expected value of the number of bits. Furthermore, the read voltage correction circuit 27 calculates the shift amounts of the read voltages based on the expected values of the number of bits (the count value of the number of bits for each state of the write data) and a count value of the number of bits for each read voltage in the read operation. The read voltage correction circuit 27 updates the bit count management table 241 and stores the shift amount for each read voltage in the bit count management table 241. Details of the shift amount calculation method will be described later.

The NAND interface circuit 28 controls communication between the memory controller 20 and the non-volatile memory 10. More specifically, the NAND interface circuit 28 transmits a command corresponding to a write operation, a read operation, an erase operation, or the like to the memory chip CP under the control of the CPU 22. Furthermore, the NAND interface circuit 28 receives read data from the memory chip CP in the read operation. The NAND interface circuit 28 may include a plurality of channels CH (CH0, CH1, . . . ). A plurality of memory chips CP (CP0, CP1, . . . ) can be coupled to each channel CH via the NAND bus NB.

### 1.1.3 Configuration of Memory Chip

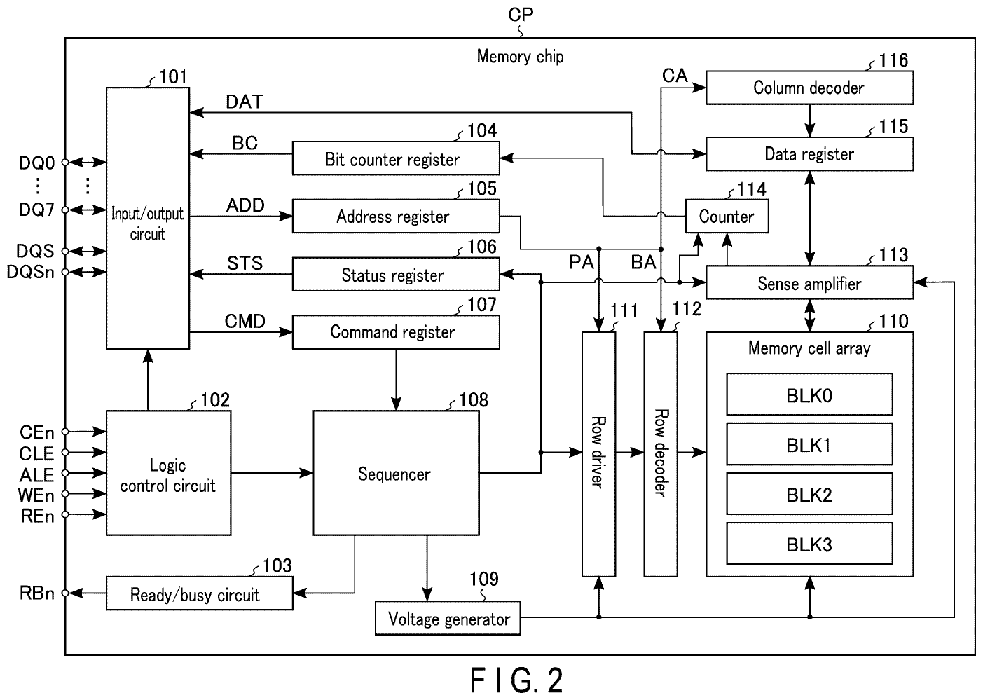

Next, an example of a configuration of the memory chip CP will be described with reference to FIG. 2. FIG. 2 is a block diagram of the memory chip CP. In the example of FIG. 2, a part of coupling of each component is indicated by an arrow line. However, the coupling between the components is not limited this.

As illustrated in FIG. 2, the memory chip CP transmits and receives a signal DQ and timing signals DQS and DQSn to and from the memory controller 20 (more specifically, the NAND interface circuit 28) via the NAND bus NB.

The signal DQ is, for example, data DAT, bit count data BC, status information STS, an address ADD, or a command CMD. For example, the data DAT is write data or read data. The bit count data BC is information on the number of bits obtained by counting data stored in a sense amplifier 113 by a counter 114. The status information STS is status information in the write operation, the read operation, and the erase operation.

The timing signals DQS and DQSn are, for example, timing signals used for input/output of the data DAT and output of the bit count data BC or the status information STS. The timing signal DQSn is an inverted signal of the timing signal DQS.

Furthermore, the memory chip CP transmits and receives various control signals to and from the memory controller 20 via the NAND bus NB. More specifically, the memory chip CP receives, for example, a chip enable signal CEn, a command latch enable signal CLE, an address latch enable signal ALE, a write enable signal WEn, and a read enable signal REn from the memory controller 20. Furthermore, the memory chip CP transmits a ready/busy signal RBn to the memory controller 20.

The chip enable signal CEn is a signal for enabling the memory chip CP. The signal CEn is asserted, for example, at a Low (“L”) level.

The command latch enable signal CLE is a signal indicating that the signal DQ is the command CMD. The signal CLE is asserted, for example, at a High (“H”) level.

The address latch enable signal ALE is a signal indicating that the signal DQ is the address ADD. The signal ALE is asserted, for example, at the “H” level.

The write enable signal WEn is a signal for taking in the signal DQ in a case where the signal DQ is the command CMD or the address ADD. The signal WEn is asserted, for example, at the “L” level at a timing when the memory chip CP takes in the command CMD or the address ADD. Therefore, every time the signal WEn is toggled, the command CMD or the address ADD is taken into the memory chip CP.

The read enable signal REn is a signal for allowing the memory controller 20 to read the data DAT, the bit count data BC, or the status information STS from the memory chip CP. The signal REn is asserted, for example, at the “L” level. For example, when outputting the signal DQ, the memory chip CP generates the signals DQS and DQSn based on the signal REn.

The ready/busy signal RBn is a signal indicating whether or not the memory chip CP can receive the command CMD from the memory controller 20. A ready state is a state in which the memory chip CP can receive the command CMD from the memory controller 20. A busy state is a state in which the memory chip CP cannot receive the command CMD from the memory controller 20. For example, the ready/busy signal RBn is in the “L” level in a case where the memory chip CP is in the busy state.

Next, an internal configuration of the memory chip CP will be described. The memory chip CP includes an input/output circuit 101, a logic control circuit 102, a ready/busy circuit 103, a bit count register 104, an address register 105, a status register 106, a command register 107, a sequencer 108, a voltage generator 109, a memory cell array 110, a row driver 111, a row decoder 112, the sense amplifier 113, the counter 114, a data register 115, and a column decoder 116.

The input/output circuit 101 inputs and outputs the signal DQ and the timing signals DQS and DQSn. The input/output circuit 101 is coupled to the memory controller 20 via the NAND bus NB. Furthermore, the input/output circuit 101 is coupled to the logic control circuit 102, the bit count register 104, the address register 105, the status register 106, the command register 107, and the data register 115.

The input/output circuit 101 transmits write data to the data register 115. The input/output circuit 101 transmits the address ADD to the address register 105. Furthermore, the input/output circuit 101 transmits the command CMD to the command register 107.

The input/output circuit 101 receives read data from the data register 115. The input/output circuit 101 receives the bit count data BC from the bit count register 104. The input/output circuit 101 receives the status information STS from the status register 106.

The logic control circuit 102 is a circuit that performs logic control of the memory chip CP. The logic control circuit 102 is coupled to the memory controller 20 via the NAND bus NB. Furthermore, the logic control circuit 102 is coupled to the input/output circuit 101 and the sequencer 108. For example, the logic control circuit 102 receives the signals CEn, CLE, ALE, WEn, and REn from the memory controller 20. The logic control circuit 102 controls the input/output circuit 101 and the sequencer 108 based on the received signals.

The ready/busy circuit 103 is a circuit that transmits the ready/busy signal RBn. The ready/busy circuit 103 transmits the ready/busy signal RBn to the memory controller 20 based on an operation status of the sequencer 108.

The bit count register 104 is a register that temporarily stores the bit count data BC. The bit count register 104 is coupled to the input/output circuit 101 and the counter 114. The bit count register 104 receives the bit count data BC from the counter 114.

The address register 105 is a register that temporarily stores the address ADD. The address register 105 is coupled to the input/output circuit 101, the row driver 111, the row decoder 112, and the column decoder 116. The address ADD includes a block address BA and a page address PA, which are row addresses, and a column address CA. The address register 105 transmits the page address PA to the row driver 111 and transmits the block address BA to the row decoder 112. Furthermore, the address register 105 transmits the column address CA to the column decoder 116.

The status register 106 is a register that temporarily stores the status information STS. The status register 106 is coupled to the input/output circuit 101 and the sequencer 108. The status register 106 receives the status information STS from the sequencer 108.

The command register 107 is a register that temporarily stores the command CMD. The command register 107 is coupled to the input/output circuit 101 and the sequencer 108. The command register 107 transmits the command CMD to the sequencer 108.

The sequencer 108 is a control circuit of the memory chip CP. The sequencer 108 controls operation of the whole memory chip CP. The sequencer 108 is coupled to the logic control circuit 102, the ready/busy circuit 103, the status register 106, the voltage generator 109, the row driver 111, the sense amplifier 113, the counter 114, and the like. For example, the sequencer 108 controls the ready/busy circuit 103, the status register 106, the voltage generator 109, the row driver 111, the sense amplifier 113, the counter 114, and the like. The sequencer 108 executes the write operation, the read operation, the erase operation, and the like based on the command CMD.

The voltage generator 109 generates voltages used for the write operation, the read operation, and the erase operation. The voltage generator 109 is coupled to the memory cell array 110, the row driver 111, the sense amplifier 113, and the like. The voltage generator 109 supplies the generated voltages to the memory cell array 110, the row driver 111, the sense amplifier 113, and the like.

The memory cell array 110 is a set of a plurality of memory cell transistors (hereinafter, also referred to as “memory cells”) arranged in a two-dimensional or three-dimensional matrix. The memory cell array 110 includes, for example, four blocks BLK0, BLK1, BLK2, and BLK3. Note that the number of blocks BLK in the memory cell array 110 may be arbitrary. The block BLK is, for example, a set of a plurality of memory cell transistors from which data is collectively erased. That is, the block BLK is a data erasing unit. Details of the configuration of the block BLK will be described later.

The row driver 111 is a driver that supplies voltages to the row decoder 112. The row driver 111 is coupled to the address register 105, the sequencer 108, the voltage generator 109, and the row decoder 112. The row driver 111 supplies voltages to the row decoder 112 based on the page address PA.

The row decoder 112 is a circuit that decodes the block address BA. The row decoder 112 is coupled to the address register 105, the row driver 111, and the memory cell array 110. The row decoder 112 selects any of the blocks BLK in the memory cell array 110 based on a result of the decoding of the block address BA.

The sense amplifier 113 is a circuit that writes and reads data. The sense amplifier 113 is coupled to the sequencer 108, the voltage generator 109, the memory cell array 110, the counter 114, and the data register 115. The sense amplifier 113 reads data from the memory cell array 110 in the read operation. Furthermore, the sense amplifier 113 supplies voltages corresponding to write data to the memory cell array 110 in the write operation.

The counter 114 is a circuit that counts the number of bits of data stored in the sense amplifier 113 under the control of the sequencer 108. The counter 114 is coupled to the bit count register 104, the sequencer 108, and the sense amplifier 113. The counter 114 counts the number of bits of “1” data read by the sense amplifier 113. More specifically, for example, the counter 114 according to the present embodiment counts the number of bits (the number) of memory cell transistors whose threshold voltage is lower than a read voltage in the read operation. In other words, for example, the counter 114 counts the number of memory cell transistors in an on state among the memory cell transistors to be read in the read operation. Note that the counter 114 may count the number of bits of “0” data read by the sense amplifier 113.

The data register 115 is a register that temporarily stores write data or read data. The data register 115 is coupled to the input/output circuit 101, the sense amplifier 113, and the column decoder 116. The data register 115 includes a plurality of latch circuits. Each latch circuit temporarily stores write data or read data.

The column decoder 116 is a circuit that decodes the column address CA. The column decoder 116 is coupled to the address register 105 and the data register 115. The column decoder 116 receives the column address CA from the address register 105. The column decoder 116 selects latch circuits in the data register 115 based on a result of the decoding of the column address CA.

### 1.1.4 Circuit Configuration of Memory Cell Array

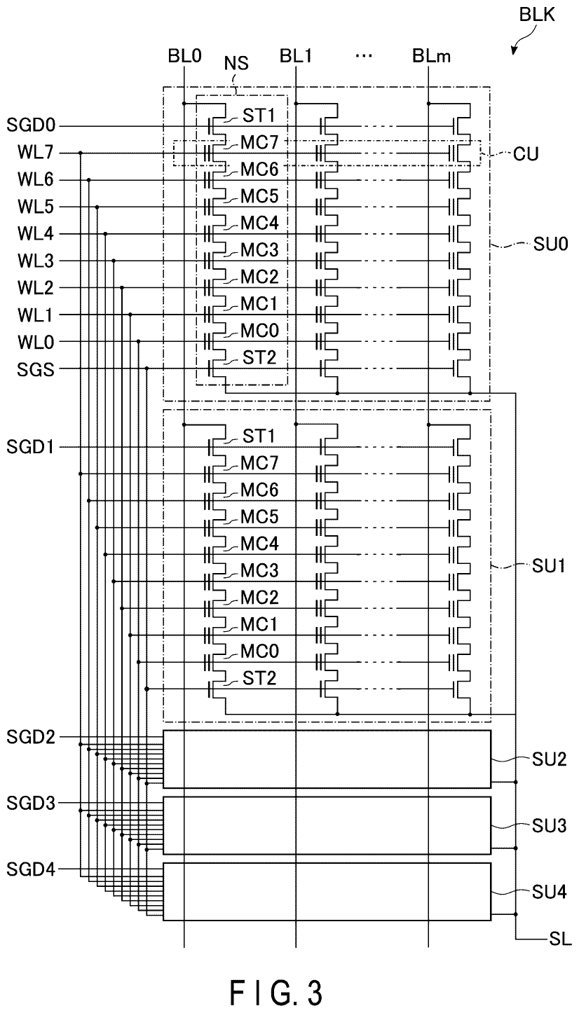

Next, an example of a circuit configuration of the memory cell array 110 will be described with reference to FIG. 3. FIG. 3 is a circuit diagram illustrating an example of a circuit configuration of the memory cell array 110.

The block BLK includes a plurality of string units SU. In the example illustrated in FIG. 3, the block BLK includes five string units SU0 to SU4. Note that the number of string units SU included in the block BLK may be arbitrary. The string unit SU is, for example, a set of a plurality of NAND strings NS.

The NAND string NS is a set of a plurality of memory cell transistors MC coupled in series. Each of the plurality of NAND strings NS in the string unit SU is coupled to any of bit lines BL0 to BLm (m is an integer of 1 or more). Each NAND string NS includes a plurality of memory cell transistors MC and selection transistors ST1 and ST2. In the example illustrated in FIG. 3, the NAND string NS includes eight memory cell transistors MC0 to MC7.

The memory cell transistor MC is a memory element that stores data in a non-volatile manner. The memory cell transistor MC includes a control gate and a charge storage layer. The memory cell transistor MC may be a metal-oxide-nitride-oxide-silicon (MONOS) type or may be a floating gate (FG) type.

The selection transistors ST1 and ST2 are switching elements. The selection transistors ST1 and ST2 are used to select the string unit SU in various operations.

Current paths of the selection transistor ST2, the memory cell transistors MC0 to MC7, and the selection transistor ST1 in the NAND string NS are coupled in series. A drain of the selection transistor ST1 is coupled to the bit line BL. A source of the selection transistor ST2 is coupled to a source line SL.

Control gates of the memory cell transistors MC0 to MC7 of all of the string units SU in the same block BLK are coupled to word lines WL0 to WL7. More specifically, for example, each of the string units SU0 to SU4 includes a plurality of memory cell transistors MC0. Control gates of the plurality of memory cell transistors MC0 in the block BLK are coupled to one word line WL0. The same applies to the memory cell transistors MC1 to MC7.

Gates of a plurality of selection transistors ST1 in each string unit SU are commonly coupled to one select gate line SGD. More specifically, the gates of the plurality of selection transistors ST1 in the string unit SU0 are commonly coupled to a select gate line SGD0. Gates of a plurality of selection transistors ST1 in the string unit SU1 are commonly coupled to a select gate line SGD1. Gates of a plurality of selection transistors ST1 in the string unit SU2 are commonly coupled to a select gate line SGD2. Gates of a plurality of selection transistors ST1 in the string unit SU3 are commonly coupled to a select gate line SGD3. Gates of a plurality of selection transistors ST1 in the string unit SU4 are commonly coupled to a select gate line SGD4.

Gates of a plurality of selection transistors ST2 in the block BLK are commonly coupled to a select gate line SGS.

The word lines WL0 to WL7, the select gate lines SGD0 to SGD4, and the select gate line SGS are coupled to the row decoder 112.

The bit line BL is commonly coupled to one NAND string NS of each of the plurality of string units SU of each block BLK. Each bit line BL is coupled to the sense amplifier 113.

The source line SL is, for example, shared among the plurality of blocks BLK.

A set of a plurality of memory cell transistors MC coupled to a common word line WL in one string unit SU is, for example, referred to as a “cell unit CU”. In other words, the cell unit CU is a set of a plurality of memory cell transistors MC collectively selected in the write operation or the read operation. A page is a unit of data that is collectively written (or collectively read) to the cell unit CU. For example, in a case where the memory cell transistors MC store 1-bit data, a storage capacity of the cell unit CU is 1 page. That is, the cell unit CU stores 1-page data. Note that the cell unit CU may have a storage capacity of 2 or more pages based on the number of bits of data stored in the memory cell transistors MC.

Hereinafter, a case where the memory cell transistor MC is triple level cell (TLC) that store 3-bit data will be described. Note that the memory cell transistor MC is not limited to the TLC. For example, the memory cell transistor MC may be single level cell (SLC) that store 1-bit data, may be multi level cell (MLC) that store 2-bit data, may be quad level cell (QLC) that store 4-bit data, or may be penta level cell (PLC) that store 5-bit data.

### 1.1.5 Configuration of Data Register and Sense Amplifier

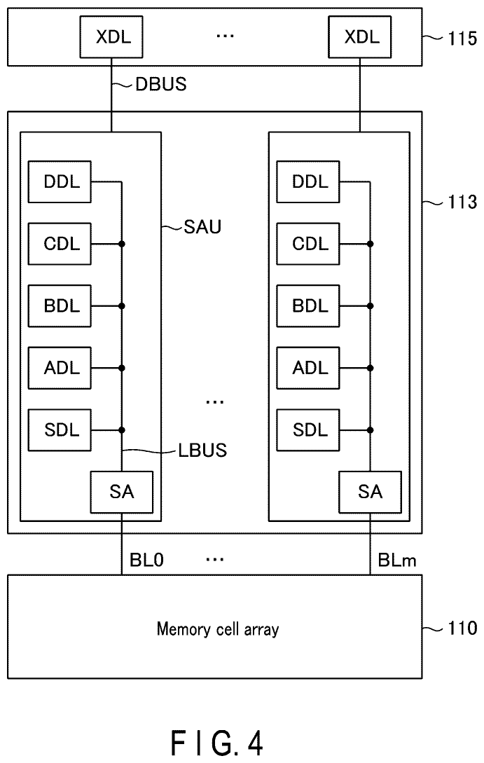

Next, an example of a configuration of the data register 115 and the sense amplifier 113 will be described with reference to FIG. 4. FIG. 4 is a block diagram of the data register 115 and the sense amplifier 113.

As illustrated in FIG. 4, the sense amplifier 113 includes a plurality of sense amplifier units SAU provided for each bit line BL.

The data register 115 includes, for example, a plurality of latch circuits XDL provided corresponding to the respective sense amplifier units SAU. The latch circuit XDL temporarily stores read data and write data. The latch circuit XDL is used for input and output of data between the sense amplifier unit SAU and the input/output circuit 101. Each latch circuit XDL is coupled to a corresponding sense amplifier unit SAU via a bus DBUS. Note that a plurality of sense amplifier units SAU may be coupled to one latch circuit XDL.

Next, an internal configuration of the sense amplifier unit SAU will be described. The sense amplifier unit SAU includes, for example, a sense circuit SA, and latch circuits SDL, ADL, BDL, CDL, and DDL. The sense circuit SA and the latch circuits SDL, ADL, BDL, CDL, and DDL are commonly coupled to a bus LBUS. In other words, the latch circuit XDL, the sense circuit SA, and the latch circuits SDL, ADL, BDL, CDL, and DDL are coupled so as to be able to transmit and receive data to and from each other.

In the read operation, the sense circuit SA senses data read to a corresponding bit line BL and determines whether the read data is “0” data or “1” data. In the write operation, the sense circuit SA applies a voltage to the bit line BL based on data stored in the latch circuit SDL. Furthermore, the sense circuit SA can execute a logical operation using the data stored in the latch circuits.

The latch circuits SDL, ADL, BDL, CDL, and DDL temporarily store read data and write data. For example, in the read operation, data can be transferred from the sense circuit SA to any of the latch circuits SDL, ADL, BDL, CDL, and DDL. In the write operation, data can be transferred from the latch circuit XDL to any of the latch circuits SDL, ADL, BDL, CDL, and DDL.

Note that the configuration of the sense amplifier unit SAU is not limited to this, and various changes can be made. For example, the number of latch circuits included in the sense amplifier unit SAU can be designed based on the number of bits of data stored in one memory cell transistor MC.

### 1.2 Threshold Voltage Distribution of Memory Cell Transistor

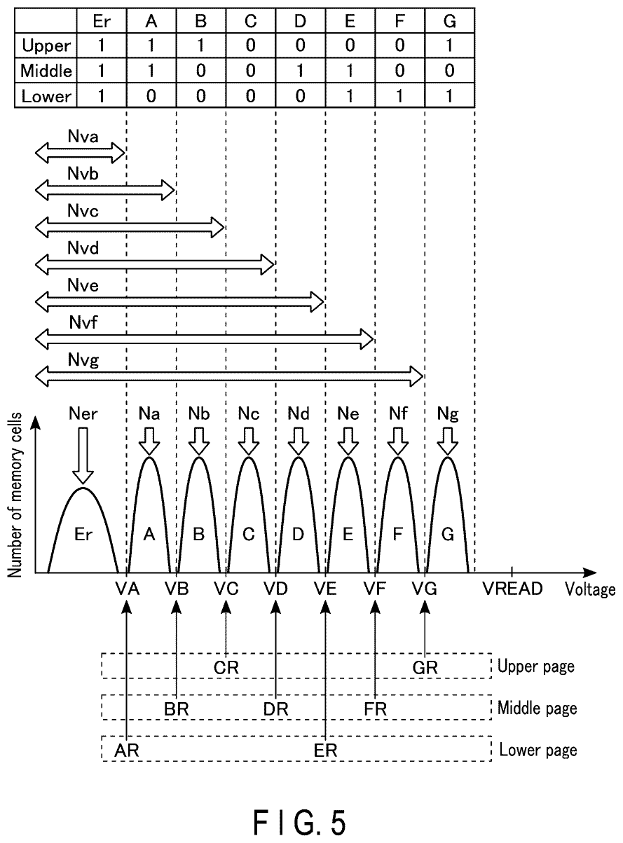

Next, an example of a threshold voltage distribution which the memory cell transistors MC can take will be described with reference to FIG. 5. FIG. 5 illustrates a relationship among a threshold voltage distribution, data allocation, and a count value of the number of bits in a case where the memory cell transistors MC are TLCs that can store 3-bit (8-value) data.

As illustrated in FIG. 5, in a case where the memory cell transistors MC are TLCs, the threshold voltage of each memory cell transistor MC takes a value included in any of discrete, for example, eight distributions. Hereinafter, the eight distributions are referred to as an “Er” state, an “A” state, a “B” state, a “C” state, a “D” state, an “E” state, an “F” state, and a “G” state in ascending order of the threshold voltage.

The “Er” state, for example, corresponds to a data erase state. Each of the “A” to “G” states corresponds to a state in which charges are injected into the charge storage layer of the memory cell transistor MC and data is written. In the write operation, verify voltages corresponding to the threshold voltage distributions are referred to as VA to VG. These voltage values have a relationship of VA<VB<VC<VD<VE<VF<VG<VREAD. A voltage VREAD is a voltage applied to a non-selected word line WL in the read operation. The memory cell transistor MC is turned on regardless of stored data upon application of the voltage VREAD to a gate of the memory cell transistor MC.

More specifically, the threshold voltage of the memory cell transistor MC included in the “Er” state is lower than the voltage VA. The threshold voltage of the memory cell transistor MC included in the “A” state is equal to or higher than the voltage VA and lower than the voltage VB. The threshold voltage of the memory cell transistor MC included in the “B” state is equal to or higher than the voltage VB and lower than the voltage VC. The threshold voltage of the memory cell transistor MC included in the “C” state is equal to or higher than the voltage VC and lower than the voltage VD. The threshold voltage of the memory cell transistor MC included in the “D” state is equal to or higher than the voltage VD and lower than the voltage VE. The threshold voltage of the memory cell transistor MC included in the “E” state is equal to or higher than the voltage VE and lower than the voltage VF. The threshold voltage of the memory cell transistor MC included in the “F” state is equal to or higher than the voltage VF and lower than the voltage VG. The threshold voltage of the memory cell transistor MC included in the “G” state is equal to or higher than the voltage VG and lower than the voltage VREAD.

In the write data, a count value (the number) of memory cell transistors MC included in the “Er” state is referred to as a count value Ner. A count value of memory cell transistors MC included in the “A” state is referred to as a count value Na. A count value of memory cell transistors MC included in the “B” state is referred to as a count value Nb. A count value of memory cell transistors MC included in the “C” state is referred to as a count value Nc. A count value of memory cell transistors MC included in the “D” state is referred to as a count value Nd. A count value of memory cell transistors MC included in the “E” state is referred to as a count value Ne. A count value of memory cell transistors MC included in the “F” state is referred to as a count value Nf. A count value of memory cell transistors MC included in the “G” state is referred to as a count value Ng.

A set value of the verify voltage and a set value of the read voltage corresponding to each state may be the same or may be different. For simplification of description, the following describes a case where the set value of the verify voltage and the set value of the read voltage are the same. That is, the read voltages corresponding to read operations of the “A” to “G” states are the voltages VA to VG, respectively.

Hereinafter, the read operations corresponding to the “A” to “G” states will be referred to as an AR read operation, a BR read operation, a CR read operation, a DR read operation, an ER read operation, an FR read operation, and a GR read operation, respectively. In the AR read operation, it is determined whether or not the threshold voltage of the memory cell transistor MC is lower than the voltage VA. In the BR read operation, it is determined whether or not the threshold voltage of the memory cell transistor MC is lower than the voltage VB. In the CR read operation, it is determined whether or not the threshold voltage of the memory cell transistor MC is lower than the voltage VC. In the DR read operation, it is determined whether or not the threshold voltage of the memory cell transistor MC is lower than the voltage VD. In the ER read operation, it is determined whether or not the threshold voltage of the memory cell transistor MC is lower than the voltage VE. In the FR read operation, it is determined whether or not the threshold voltage of the memory cell transistor MC is lower than the voltage VF. In the GR read operation, it is determined whether or not the threshold voltage of the memory cell transistor MC is lower than the voltage VG.

In the AR read operation, a count value of the memory cell transistors MC whose threshold voltage is lower than the voltage VA is referred to as a count value Nva. In the BR read operation, a count value of the memory cell transistors MC whose threshold voltage is lower than the voltage VB is referred to as a count value Nvb. In the CR read operation, a count value of the memory cell transistors MC whose threshold voltage is lower than the voltage VC is referred to as a count value Nvc. In the DR read operation, a count value of the memory cell transistors MC whose threshold voltage is lower than the voltage VD is referred to as a count value Nvd. In the ER read operation, a count value of the memory cell transistors MC whose threshold voltage is lower than the voltage VE is referred to as a count value Nve. In the FR read operation, a count value of the memory cell transistors MC whose threshold voltage is lower than the voltage VF is referred to as a count value Nvf. In the GR read operation, a count value of the memory cell transistors MC whose threshold voltage is lower than the voltage VG is referred to as a count value Nvg.

The memory cell transistor MC has any of eight threshold voltage distributions and therefore can take eight types of states. By assigning these states to “000” to “111” in binary notation, each memory cell transistor MC can store 3-bit data. Hereinafter, the 3-bit data are referred to as a “lower bit”, a “middle bit”, and an “upper bit”, respectively. A set of lower bits collectively written (or read) to the cell unit CU is referred to as “lower page data”, a set of middle bits is referred to as “middle page data”, and a set of upper bits is referred to as “upper page data”.

In the example of FIG. 5, data is allocated to “upper bit/middle bit/lower bit” for the memory cell transistors MC included in each threshold voltage distribution as follows.
“Er” state: “111” data
“A” state: “110” data
“B” state: “100” data
“C” state: “000” data
“D” state: “010” data
“E” state: “011” data
“F” state: “001” data
“G” state: “101” data

In a case where the data thus allocated is read, the lower bit is determined by the AR read operation and the ER read operation. The middle bit is determined by the BR read operation, the DR read operation, and the FR read operation. The upper bit is determined by the CR read operation and the GR read operation. That is, the values of the lower bit, the middle bit, and the upper bit are determined by two, three, and two read operations, respectively. Hereinafter, this data allocation is referred to as “2-3-2 code”. Note that data allocation to the “Er” to “G” states is not limited to the 2-3-2 code.

### 1.3 Bit Count Management Table

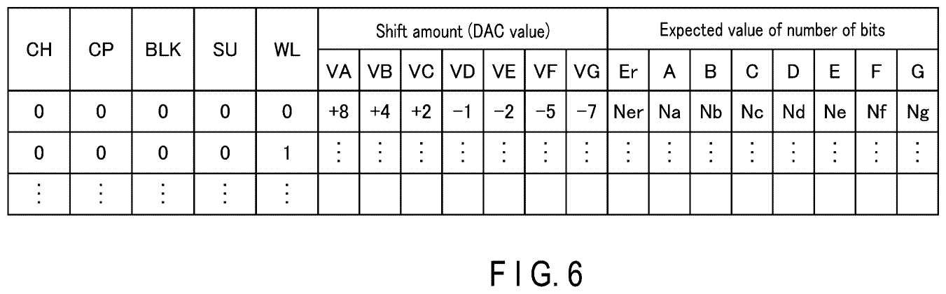

Next, an example of the bit count management table 241 will be described with reference to FIG. 6. FIG. 6 illustrates an example of the bit count management table 241.

As illustrated in FIG. 6, in the bit count management table 241, information on the cell unit CU for which the shift amounts of the read voltages are to be calculated, information on the shift amounts of the read voltages, and expected values of the number of bits are set.

For example, in the bit count management table 241, information on the channel CH, the memory chip CP, the block BLK, the string unit SU, and the word line WL is stored as the information on the cell unit CU. In the example illustrated in FIG. 6, the channel CH0, the memory chip CP0, the block BLK0, the string unit SU0, and the word lines WL0 and WL1 are stored in the bit count management table 241.

The cell unit CU for which the shift amount of the read voltage is to be calculated may be all the cell units CU or may be a representative cell unit CU (hereinafter, also referred to as an “anchor”) in a group of a plurality of cell units CU. In a case where the shift amount is to be calculated for all the cell units CU, information on all the cell units CU is stored in the bit count management table 241. In a case where the anchor is set, information on the anchor is stored in the bit count management table 241. For example, the group of cell units CU may be determined in units of the channel CH, may be determined in units of the memory chip CP, may be determined in units of the block BLK, may be determined in units of the string unit SU, or may be determined in units of a plurality of word lines WL. In other words, the shift amount can be individually set per channel CH, per memory chip CP, per block BLK, per string unit SU, or per a plurality of word lines WL.

The shift amount is, for example, stored as a digital to analogue converter (DAC) value. For example, in a case where the DAC value is 0, a default value (the voltages VA to VG described with reference to FIG. 5) is set as the read voltage. That is, the read voltage is not shifted. In the example illustrated in FIGS. 6, +8, +4, +2, −1, −2, −5, and −7 are stored as the shift amounts of the read voltages VA to VG used in the AR to GR read operations, respectively. In a case where the DAC value is a positive value, the read voltage is shifted from the default value to a high voltage side. In a case where the DAC value is a negative value, the read voltage is shifted from the default value to a low voltage side.

As the expected values of the number of bits, count values Ner, Na, Nb, Nc, Nd, Ne, Nf, and Ng of write data of the target cell unit CU are stored.

### 1.4 Shift Amount Calculation Method

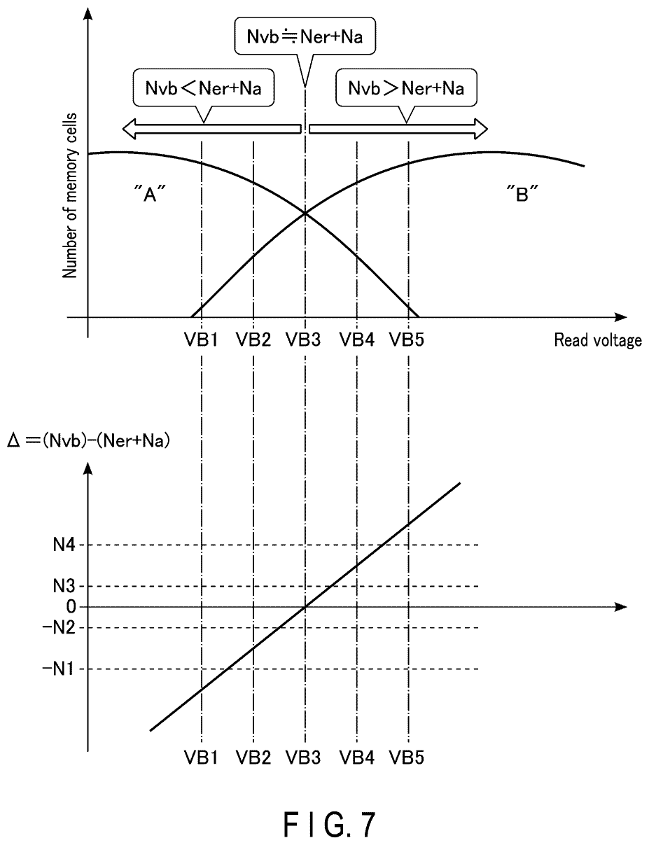

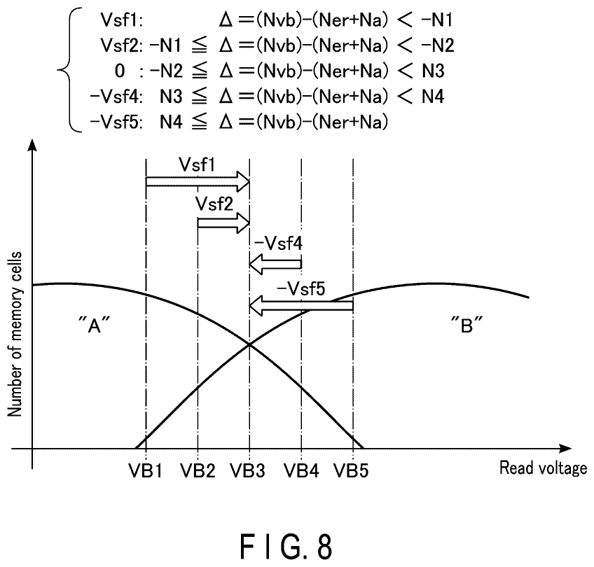

Next, a method for calculating the shift amount will be described with reference to FIGS. 7 and 8. FIG. 7 is a conceptual diagram illustrating a relationship between the count value Nvb and a count value (Ner+Na) corresponding to the read voltage VB. FIG. 8 is a conceptual diagram illustrating an example of a relationship between a difference between the count value Nvb and the count value (Ner+Na) and the shift amount. Although the following description will be given focusing on the BR read operation (the read voltage VB), the same applies to the AR and CR to GR read operations (the read voltages VA and VC to VG).

For example, the threshold voltage distributions of the respective states immediately after the write operation are separated from each other, as described with reference to FIG. 5. Therefore, the states can be distinguished by the read voltages VA to VG. For example, in the case of the BR read operation, the count value Nvb of the memory cell transistors MC lower than the read voltage VB is equal to the sum of the count value Ner of the memory cell transistors MC in the “Er” state and the count value Na of the memory cell transistors MC in the “A” state, that is, the count value (Ner+Na). In other words, the count value Nvb is equal to the sum (Ner+Na) of the expected value of the number of bits of the “Er” state and the expected value of the number of bits of the “A” state.

However, due to influence of read disturb, data retention, or the like, a width of the threshold voltage distribution of each state may be expanded, and portions of tails of adjacent threshold voltage distributions may overlap each other. The read disturb is a phenomenon in which the threshold voltage of the memory cell transistor MC is shifted to the high voltage side due to injection of charges into the charge storage layer during the read operation. The data retention is a phenomenon in which the threshold voltage of the memory cell transistor MC is shifted to the low voltage side due to release of charges from the charge storage layer. In a case where the read operation is executed in such a state, the memory cell transistor MC corresponding to the tail overlapping region is highly likely to be a fail bit. The relationship between the count value Nvb and the count value (Ner+Na) changes depending on shapes of the threshold voltage distributions.

As illustrated in the upper part of FIG. 7, for example, in a case where the BR read operation is executed, the memory cell transistor MC of the “A” state having a threshold voltage equal to or higher than the read voltage VB and the memory cell transistor MC of the “B” state having a threshold voltage lower than the read voltage VB become fail bits. In a case where the number of generated fail bits exceeds the number of error correctable bits of the ECC circuit 26, the read data cannot be decoded.

For example, the count value Nvb includes a count value of the memory cell transistors MC in the “Er” state, a count value of the memory cell transistors MC in the “A” state having a threshold voltage lower than the voltage VB, and a count value of the memory cell transistors MC in the “B” state having a threshold voltage lower than the voltage VB.

FIG. 7 illustrates voltages VB1 to VB5 as examples of the position of the read voltage VB. For example, the voltage VB3 indicates a valley position between the threshold voltage distribution of the “A” state and the threshold voltage distribution of the “B” state. In a case where it can be considered that the shapes of the two threshold voltage distributions are almost equal, a count value of the memory cell transistors MC in the “A” state having a threshold voltage equal to or higher than the voltage VB3 and a count value of the memory cell transistors MC in the “B” state having a threshold voltage lower than the voltage VB3 are almost equal. In this case, the count value Nvb of the memory cell transistors MC lower than the voltage VB3 can be almost equal to the count value (Ner+Na). Therefore, as illustrated in the lower part of FIG. 7, a difference A (=Nvb−(Ner+Na)) between the count value Nvb and the count value (Ner+Na) is almost 0.

For example, as the position of the read voltage VB shifts from the voltage VB3 to the voltage VB2 and to the voltage VB1 on the low voltage side, the count value Nvb decreases. Therefore, as illustrated in the lower part of FIG. 7, the value of the difference A, that is, Nvb−(Ner+Na) decreases and becomes a negative value. On the other hand, as the position of the read voltage VB shifts from the voltage VB3 to the voltage VB4 and to the voltage VB5 on the high voltage side, the count value Nvb increases. Therefore, the difference A increases and becomes a positive value.

As illustrated in the lower part of FIG. 7 and FIG. 8, in the present embodiment, the magnitude of the difference A is classified into five sections. Note that the number of sections is not limited to five. Different shift amounts are set for the respective sections. For example, reference values −N1, −N2, N3, and N4 are set as values indicating boundaries between sections. The reference values −N1, −N2, N3, and N4 have a relationship of −N1<−N2<0<N3<N4.

For example, the difference Δ corresponding to the voltage VB1 is smaller than the reference value −N1 (Δ<−N1). In this case, a shift amount Vsf1 is set. The shift amount Vsf1 is a positive value (0<Vsf1). In the BR read operation, a read voltage (VB+Vsf1) is set.

For example, the difference Δ corresponding to the voltage VB2 is equal to or larger than the reference value −N1 and smaller than the reference value −N2 (−N1≤Δ<−N2). In this case, a shift amount Vsf2 is set. The shift amount Vsf2 is a positive value smaller than the shift amount Vsf1 (0<Vsf2<Vsf1). In the read operation, a BR read voltage (VB+Vsf2) is set.

For example, the difference Δ corresponding to the voltage VB3 is equal to or larger than the reference value −N2 and smaller than the reference value N3 (−N2≤Δ<N3). In this case, 0 is set as the shift amount. In the BR read operation, the read voltage VB (default value) is set.

For example, the difference Δ corresponding to the voltage VB4 is equal to or larger than the reference value N3 and smaller than the reference value N4 (N3≤Δ<N4). In this case, a shift amount −Vsf4 is set. The shift amount −Vsf4 is a negative value (−Vsf4<0). In the BR read operation, a read voltage (VB−Vsf4) is set.

For example, the difference Δ corresponding to the voltage VB5 is equal to or larger than the reference value N4 (N4<Δ). In this case, a shift amount −Vsf5 is set. The shift amount −Vsf5 is a negative value smaller than the shift amount −Vsf4 (−Vsf5<−Vsf4<0). In the BR read operation, a read voltage (VB−Vsf5) is set.

The difference Δ is calculated for the AR and CR to GR read operations in a similar manner.

In the case of the AR read operation, the read voltage correction circuit 27 calculates a difference Δ (=Nva−Ner) between the count value Nva of the memory cell transistors MC lower than the read voltage VA and the expected value of the number of bits of the “Er” state, that is, the count value Ner.

In the case of the CR read operation, the read voltage correction circuit 27 calculates a difference Δ (=Nvc−(Ner+Na+Nb)) between the count value Nvc of the memory cell transistors MC lower than the read voltage VC and the sum of the expected values of the number of bits of the “Er”, “A”, and “B” states, that is, the count value (Ner+Na+Nb).

In the case of the DR read operation, the read voltage correction circuit 27 calculates a difference Δ (=Nvd−(Ner+Na+Nb+Nc)) between the count value Nvd of the memory cell transistors MC lower than the read voltage VD and the expected values of the number of bits of the “Er” and “A” to “C” states, that is, the count value (Ner+Na+Nb+Nc).

In the case of the ER read operation, the read voltage correction circuit 27 calculates a difference Δ (=Nve−(Ner+Na+Nb+Nc+Nd)) between the count value Nve of the memory cell transistors MC lower than the read voltage VE and the sum of expected values of the number of bits of the “Er” and “A” to “D” states, that is, the count value (Ner+Na+Nb+Nc+Nd).

In the case of the FR read operation, the read voltage correction circuit 27 calculates a difference Δ (=Nvf−(Ner+Na+Nb+Nc+Nd+Ne)) between the count value Nvf of the memory cell transistors MC lower than the read voltage VF and the sum of expected values of the number of bits of the “Er” and “A” to “E” states, that is, the count value (Ner+Na+Nb+Nc+Nd+Ne).

In the case of the GR read operation, the read voltage correction circuit 27 calculates a difference Δ (=Nvg−(Ner+Na+Nb+Nc+Nd+Ne+Nf)) between the count value Nvg of the memory cell transistors MC lower than the read voltage VG and the sum of the expected values of the number of bits of the “Er” and “A” to “F” states, that is, the count value (Ner+Na+Nb+Nc+Nd+Ne+Nf). Instead of calculating the count value (Ner+Na+Nb+Nc+Nd+Ne+Nf), (the number of memory cell transistors MC included in the cell unit CU-Ng) may be calculated. The count value (the number of memory cell transistors MC included in the cell unit CU-Ng) is equal to the count value (Ner+Na+Nb+Nc+Nd+Ne+Nf).

Note that the reference values −N1, −N2, N3, and N4 may vary depending on the read voltage or may be the same irrespective of the read voltage.

### 1.5 Write Operation

Next, a flow of the write operation will be described.

### 1.5.1 Overall Flow of Write Operation

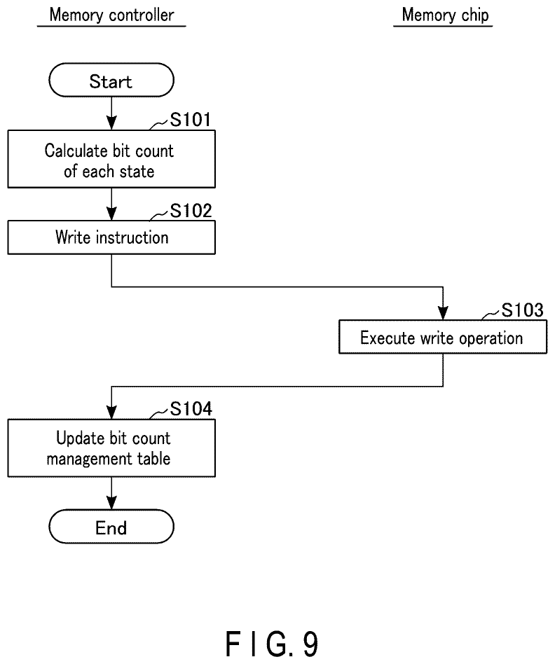

First, an example of overall flow of the write operation will be described with reference to FIG. 9. FIG. 9 is a flowchart illustrating an example of the overall flow of the write operation. Note that FIG. 9 illustrates a case where all the write data is a target of counting of the number of bits.

As illustrated in FIG. 9, upon receipt of a write request from the host 2, the ECC circuit 26 generates write data by giving parity to user data. The read voltage correction circuit 27 calculates a bit count of each state by referring to the write data (S101). Note that in a case where not all the cell units CU are a target of calculation of the shift amount of the read voltage, the CPU 22 executes step S101 on write data written to an anchor (cell unit CU).

After calculating the bit count, the CPU 22 instructs the non-volatile memory 10 to execute the write operation (S102). That is, the memory controller 20 transmits a command set instructing execution of the write operation to the memory chip CP. The command set of the write operation includes a writing execution command, an address, and the write data.

The sequencer 108 executes the write operation based on the command set of the write operation (S103).

In a case where the write operation in the memory chip CP is ended, the read voltage correction circuit 27 updates the bit count management table 241 (S104). More specifically, the read voltage correction circuit 27 stores a result of the bit count for each state as an expected value of the number of bits in the bit count management table 241.

### 1.5.2 Flow of Write Data in Memory Chip

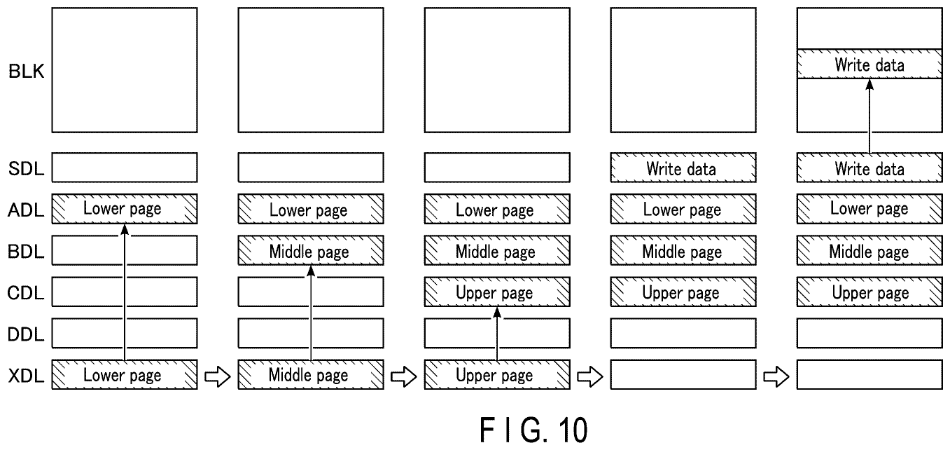

Next, an example of flow of write data in the memory chip CP will be described with reference to FIG. 10. FIG. 10 illustrates an example of flow of write data in the memory chip CP. FIG. 10 illustrates a case where the lower page data, the middle page data, and the upper page data are collectively written.

As illustrated in FIG. 10, first, the lower page data is input to the latch circuit XDL of the data register 115. The lower page data of the latch circuit XDL is, for example, transferred to the latch circuit ADL of the sense amplifier 113.

Next, the middle page data is input to the latch circuit XDL of the data register 115. The middle page data of the latch circuit XDL is, for example, transferred to the latch circuit BDL of the sense amplifier 113.

Next, the upper page data is input to the latch circuit XDL of the data register 115. The upper page data of the latch circuit XDL is, for example, transferred to the latch circuit CDL of the sense amplifier 113.

Next, the sense circuit SA calculates data to be written to a cell unit CU selected as a write target by executing computation using the lower page data, the middle page data, and the upper page data, and stores the data in the latch circuit SDL.

Next, the sense circuit SA writes the write data of the latch circuit SDL to the cell unit CU.

### 1.5.3 Command Sequence

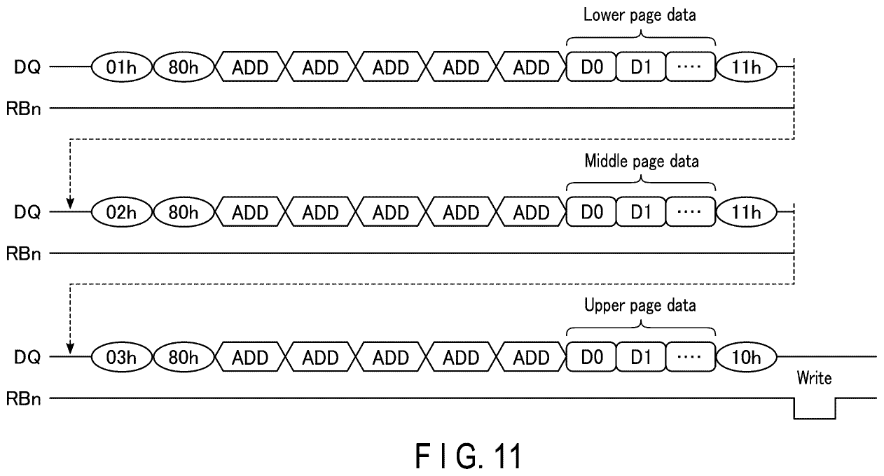

Next, an example of a command sequence of the write operation will be described with reference to FIG. 11. FIG. 11 is a timing chart illustrating an example of a command sequence of the write operation.

As illustrated in FIG. 11, first, the memory controller 20 transmits a command “01h” and a command “80h” to the memory chip CP. The command “01h” is a prefix command designating the lower page. The command “80h” is a command giving a notification of execution of the write operation. Next, the memory controller 20 transmits, for example, 5 cycles of the address “ADD”. Note that the number of cycles of the address may be arbitrary. The address may include information designating the lower page. In this case, the command “01h” may be omitted. Next, the memory controller 20 transmits the lower page data (plural cycles of data D0, D1, . . . ) to the memory chip CP. Next, the memory controller 20 transmits a command “11h” to the memory chip CP. The command “11h” is a command giving a notification that the write operation is a write operation of a plurality of pages. Upon receipt of the command “11h”, the sequencer 108 stores the lower page data, for example, in the latch circuit ADL.

Next, the memory controller 20 sequentially transmits commands “02h” and “80h”, 5 cycles of the address “ADD”, the middle page data, and the command “11h” to the memory chip CP. The command “02h” is a command designating the middle page. Note that the address may include information designating the middle page. In this case, the command “02h” may be omitted. Upon receipt of the command “11h”, the sequencer 108 stores the middle page data, for example, in the latch circuit BDL.

Next, the memory controller 20 sequentially transmits commands “03h” and “80h”, 5 cycles of the address “ADD”, the upper page data, and a command “10h” to the memory chip CP. The command “03h” is a command designating the upper page. Note that the address may include information designating the upper page. In this case, the command “03h” may be omitted. The command “10h” is a command instructing execution of the write operation. Upon receipt of the command “10h”, the sequencer 108 sets the ready/busy signal RBn to the “L” level. Then, after storing the upper page data, for example, in the latch circuit CDL, the sequencer 108 executes the write operation based on the lower page data, the middle page data, and the upper page data.

In a case where the write operation is ended, the sequencer 108 sets the ready/busy signal RBn to the “H” level.

### 1.6 Read Operation

Next, the read operation will be described. The read operation of the present embodiment includes a normal read operation and a bit count read operation. The normal read operation is an operation of reading data from the selected cell unit CU. The bit count read operation includes an operation of reading data from the selected cell unit CU and a count operation of counting the number of bits of the read data.

Although the following description will be given focusing on the read operation of the lower page data, the same applies to the read operation of the middle page data and the upper page data.

### 1.6.1 Data Allocation in Read Operation of Lower Page Data

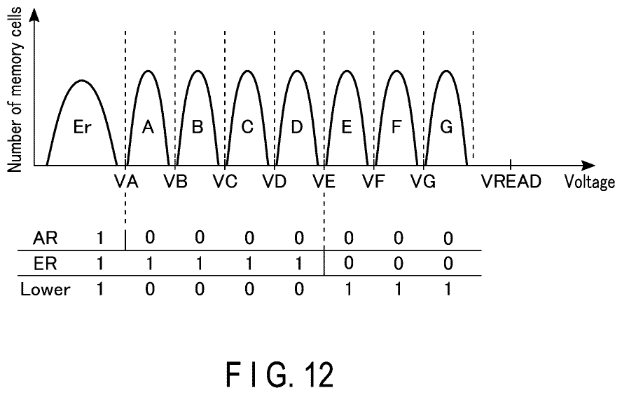

First, an example of data allocation in the read operation of the lower page data will be described with reference to FIG. 12. FIG. 12 illustrates an example of data allocation in the read operation of the lower page data.

As illustrated in FIG. 12, in the read operation of the lower page data, the AR read operation and the ER read operation are executed. For example, in the AR read operation, “1” is allocated to the “Er” state lower than the threshold voltage VA, and “0” is allocated to the “A” to “G” states. For example, the counter 114 counts “1”. That is, the counter 114 counts the number of memory cell transistors MC in the “Er” state as the count value Ner. Furthermore, in the ER read operation, “1” is allocated to the “Er” and “A” to “D” states lower than the threshold voltage VE, and “0” is allocated to the “E” to “G” states. The counter 114 counts the number of memory cell transistors MC in the “Er” and “A” to “D” states as the count value Ne. For example, the lower page data is calculated by an exclusive OR (EXOR) operation of the read data of the AR read operation and inverted data of the read data of the ER read operation.

### 1.6.2 Overall Flow of Bit Count Read Operation

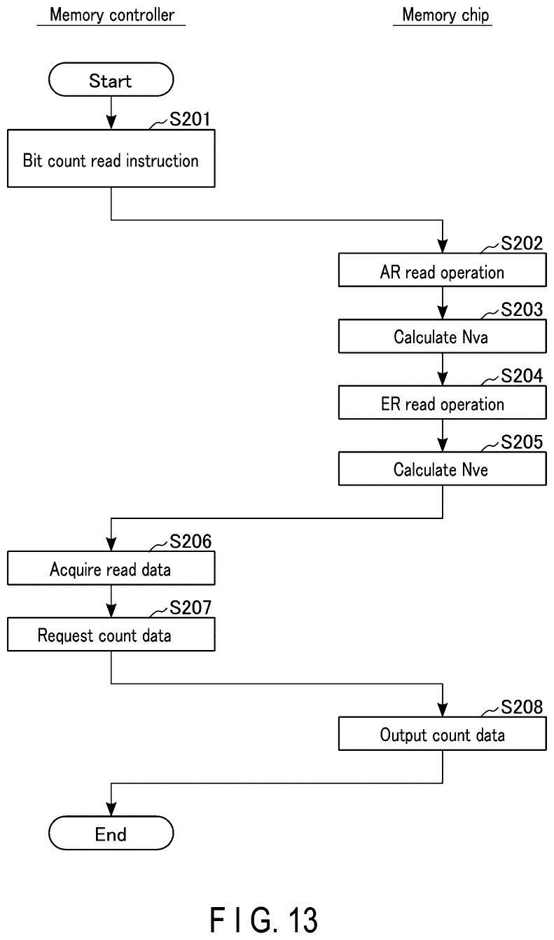

Next, an example of overall flow of the bit count read operation will be described with reference to FIG. 13. FIG. 13 is a flowchart illustrating an example of the overall flow of the bit count read operation of the lower page data.

As illustrated in FIG. 13, the memory controller 20 instructs the non-volatile memory 10 to execute the bit count read operation (S201). That is, the memory controller 20 transmits a command set instructing execution of the bit count read operation to the memory chip CP.

In a case where read target data is the lower page data, the sequencer 108 first executes the AR read operation based on the command set of the bit count read operation (S202).

In a case where the AR read operation is ended, the counter 114 counts data (hereinafter, also referred to as “AR data”) read by the AR read operation. In other words, the counter 114 calculates the count value Nva (S203). The counter 114 causes the bit count register 104 to store the count value Nva as bit count data BC.

Next, the sequencer 108 executes the ER read operation (S204). Note that the sequencer 108 may execute the calculation of the count value Nva in step S203 and the ER read operation in step S204 in parallel.

In a case where the ER read operation is ended, the counter 114 counts data (hereinafter, also referred to as “ER data”) read by the ER read operation. In other words, the counter 114 calculates the count value Nve (S205). The counter 114 causes the bit count register 104 to store the count value Nve as bit count data BC.

Upon confirming that the read operation has ended in the memory chip CP, the memory controller 20 acquires the read data (for example, the lower page data) from the memory chip CP (S206).

Next, the memory controller 20 requests the bit count data BC (the count values Nva and Nve) from the memory chip CP (S207).

The memory chip CP outputs the bit count data BC to the memory controller 20 (S208). In other words, the memory controller 20 acquires the bit count data BC from the memory chip CP.

Note that the overall flow of the bit count read operation of the lower page data is not limited to this. For example, the memory chip CP may calculate the count values Nva and Nve after the AR read operation and the ER read operation are ended. Furthermore, the memory chip CP may calculate the count values Nva and Nve after receiving a bit count execution request from the memory controller 20. Furthermore, the memory controller 20 may acquire only the bit count data BC without acquiring the read data (lower page data) from the memory chip CP.

### 1.6.3 Flow of Read Data in Memory Chip

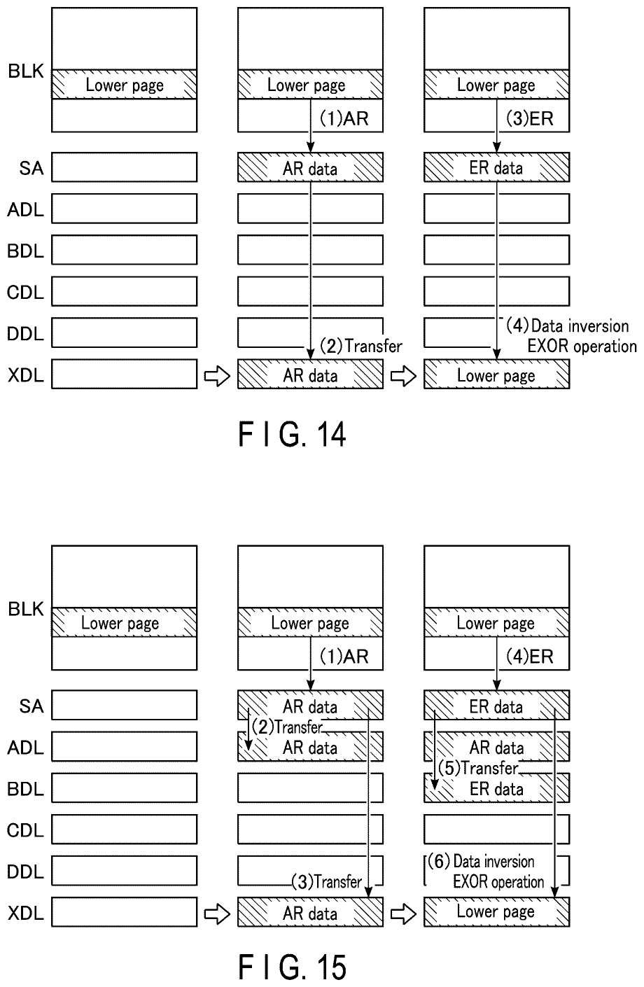

Next, an example of flow of read data in the memory chip CP will be described with reference to FIGS. 14 and 15. FIG. 14 illustrates an example of flow of the lower page data in the normal read operation. FIG. 15 illustrates an example of flow of the lower page data in the bit count read operation.

First, flow of the lower page data in the normal read operation will be described.

As illustrated in FIG. 14, first, the sequencer 108 executes the AR read operation in a selected cell unit CU to be read (1). The sense circuit SA transfers the AR data to the latch circuit XDL (2). Next, the sequencer 108 executes the ER read operation (3). The sense circuit SA transfers a result of executing the EXOR operation on the AR data and the inverted data of the ER data, that is, the lower page data to the latch circuit XDL (4).

Next, the bit count read operation of the lower page data will be described.

As illustrated in FIG. 15, first, the sequencer 108 executes the AR read operation in the cell unit CU to be read in a similar manner to the normal read operation (1). The sense circuit SA transfers the AR data to the latch circuit ADL (2). Furthermore, the sense circuit SA transfers the AR data to the latch circuit XDL (3). Next, the sequencer 108 executes the ER read operation (4). The sense circuit SA transfers the ER data to the latch circuit BDL (5). Next, the sense circuit SA transmits the inverted data of the ER data to the latch circuit XDL and executes an EXOR operation. In this way, the lower page data is stored in the latch circuit XDL (6).

For example, the counter 114 counts “1” data included in the AR data stored in the latch circuit ADL and calculates the count value Nva. Furthermore, the counter 114 counts “1” data included in the ER data stored in the latch circuit BDL and calculates the count value Nve. The count values Nva and Nve are stored in the bit count register 104.

For example, in the case of the bit count read operation of the middle page data, the BR data read by the BR read operation is stored in the latch circuit ADL, the DR data read by the DR read operation is stored in the latch circuit BDL, and the FR data read by the FR read operation is stored in the latch circuit CDL. For example, in the case of the bit count read operation of the upper page data, the CR data read by the CR read operation is stored in the latch circuit ADL, and the GR data read by the GR read operation is stored in the latch circuit BDL.

### 1.6.4 Command Sequence of Read Operation

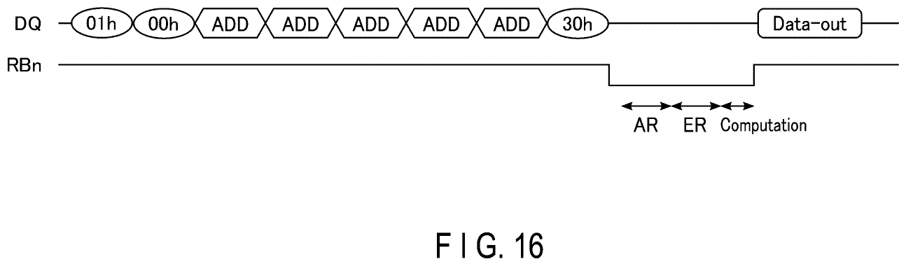

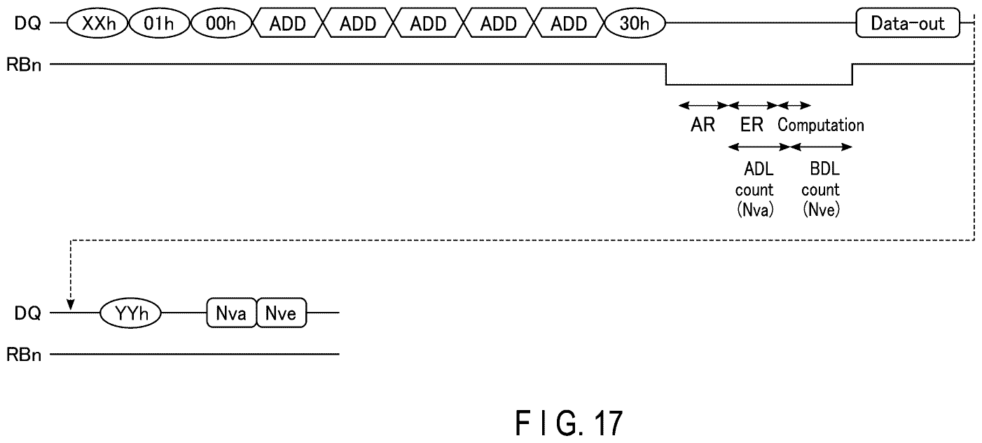

Next, an example of a command sequence of the read operation will be described with reference to FIGS. 16 and 17. FIG. 16 is a timing chart illustrating an example of a command sequence of the normal read operation of the lower page data. FIG. 17 is a timing chart illustrating an example of a command sequence of the bit count read operation of the lower page data.

First, the normal read operation of the lower page data will be described.

As illustrated in FIG. 16, first, the memory controller 20 transmits a command “01h” and a command “00h” to the memory chip CP. The command “01h” is a prefix command designating the lower page. The command “00h” is a command giving a notification of execution of the read operation. Next, the memory controller 20 transmits, for example, 5 cycles of the address “ADD”. Note that the number of cycles of the address may be arbitrary. The address may include information designating the lower page. In this case, the command “01h” may be omitted. Next, the memory controller 20 transmits a command “30h” instructing execution of the read operation to the memory chip CP.

Upon receipt of the command “30h”, the sequencer 108 sets the ready/busy signal RBn to the “L” level. Then, the sequencer 108 executes the normal read operation of the lower page data based on the command “01h”. More specifically, for example, the AR read operation, the ER read operation, and the EXOR operation are executed. In a case where the lower page data is stored in the latch circuit XDL, the sequencer 108 sets the ready/busy signal RBn to the “H” level.

After confirming that the ready/busy signal RBn is at the “H” level, the memory controller 20 causes the memory chip CP to output the read data (Data-out).

Next, the bit count read operation of the lower page data will be described.

As illustrated in FIG. 17, first, the memory controller 20 transmits a prefix command “XXh” indicating the bit count read operation to the memory chip CP. Next, similarly to the normal read operation, the memory controller 20 sequentially transmits the commands “01h” and “00h”, 5 cycles of the address “ADD”, and command “30h” to the memory chip CP.

Upon receipt of the command “30h”, the sequencer 108 sets the ready/busy signal RBn to the “L” level. Then, the sequencer 108 executes the bit count read operation of the lower page data based on the command “01h”. For example, the AR read operation, the ER read operation, and the EXOR operation are sequentially executed. In parallel with this, the counter 114 sequentially executes counting of the AR data stored in the latch circuit ADL (calculation of the count value Nva) and counting of the ER data stored in the latch circuit BDL (calculation of the count value Nve). In a case where the counting of the latch circuit BDL is ended, the sequencer 108 sets the ready/busy signal RBn to the “H” level.

After confirming that the ready/busy signal RBn is at the “H” level, the memory controller 20 causes the memory chip CP to output the read data (Data-out).

Next, the memory controller 20 transmits a command “YYh” to the memory chip CP. The command “YYh” is a command requesting the bit count data BC from the memory chip CP. Next, the memory controller 20 causes the memory chip CP to output the count values Nva and Nve as the bit count data BC.

### 1.7 Application Example of Bit Count Read Operation

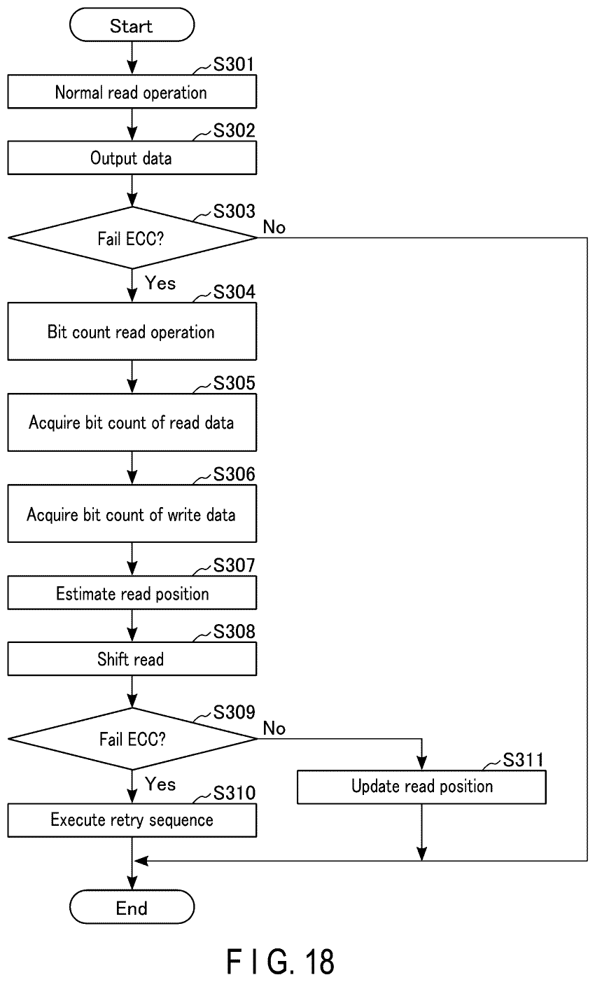

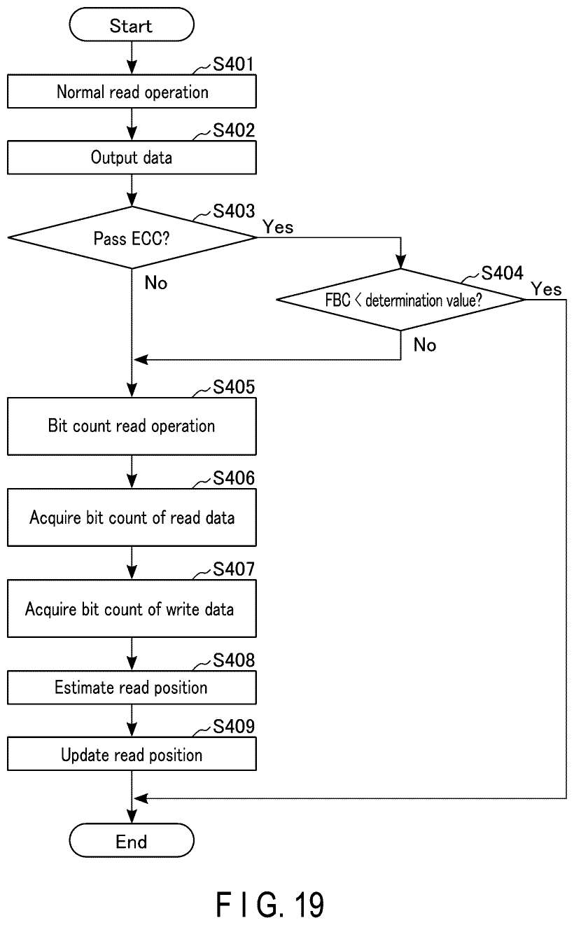

Next, an application example of the bit count read operation will be described with reference to FIGS. 18 and 19. FIG. 18 is a flowchart illustrating an example in which the bit count read operation is applied to the host read. FIG. 19 is a flowchart illustrating an example in which the bit count read operation is applied to the patrol read.

First, an example in which the bit count read operation is applied to the host read will be described.

As illustrated in FIG. 18, upon receipt of a read request from the host 2, the CPU 22 causes the memory chip CP to execute the normal read operation of the selected cell unit CU (S301). For example, in a case where information on a shift amount corresponding to the selected cell unit CU is stored in the bit count management table 241, the CPU 22 transmits a command set (Set Feature) of parameter setting concerning a shift amount of the read voltage and a command set of the read operation to the memory chip CP. In this case, the sequencer 108 executes the normal read operation using the shifted read voltage.

In a case where the normal read operation is completed, the sequencer 108 outputs read data to the memory controller 20 (S302).

The ECC circuit 26 executes ECC processing (decoding processing) of the read data. In a case where the ECC circuit 26 passes the ECC processing (S303_No), the CPU 22 transmits decoded user data to the host 2 and ends the host read.

In a case where the ECC circuit 26 fails the ECC processing (S303_Yes), the CPU 22 causes the memory chip CP to execute the bit count read operation (S304). More specifically, the CPU 22 transmits a command set of the bit count read operation to the memory chip CP. Upon receipt of the command set, the sequencer 108 executes the bit count read operation. Note that in a case where the selected cell unit CU is not an anchor, the CPU 22 can cause the memory chip CP to execute the bit count read operation of the anchor.

In a case where the bit count read operation ends in the memory chip CP, the read voltage correction circuit 27 acquires a bit count (bit count data BC) of read data from the memory chip CP (S305). In other words, the read voltage correction circuit 27 acquires a count value for each read voltage from the memory chip CP.

Next, the read voltage correction circuit 27 acquires expected values of the number of bits (a count value of write data for each state) by referring to the bit count management table 241 (S306).

The read voltage correction circuit 27 estimates (determines) a read position (shift amount) for each read voltage based on the bit count data BC (the count value for each read voltage) and the expected value of the number of bits (the count value of the write data for each state) (S307).

The CPU 22 transmits a command set of parameter setting concerning the estimated read position (shift amount) and a command set of the read operation to the memory chip CP. The sequencer 108 shifts the read voltage and executes the normal read operation of the selected cell unit CU (hereinafter, also referred to as “shift read”) (S308).

In a case where the shift read is ended, the sequencer 108 outputs read data to the memory controller 20. The ECC circuit 26 executes ECC processing of the read data. In a case where the ECC circuit 26 fails the ECC processing (S309 Yes), the CPU 22 executes a retry sequence (S310). For example, in the retry sequence, shift read using a read voltage for which a shift amount is set in advance, soft bit decoding processing, tracking read, and the like are executed. The soft bit decoding processing is decoding processing using a read soft bit decoding value (soft bit). The tracking read is an operation of searching for an optimum read voltage by repeating read operation plural times while shifting the read voltage.

In a case where the ECC circuit 26 passes the ECC processing (S309_No), the read voltage correction circuit 27 updates the read position (S311). That is, the read voltage correction circuit 27 updates the information concerning the shift amount in the bit count management table 241.

Next, an example in which the bit count read operation is applied to the patrol read will be described.

As illustrated in FIG. 19, first, the CPU 22 causes a patrol target memory chip CP to execute the normal read operation of the anchor as in step S301 described with reference to FIG. 18 (S401).

In a case where the normal read operation is ended, the sequencer 108 outputs read data to the memory controller 20 as in step S302 (S402).

The ECC circuit 26 executes ECC processing of the read data. In a case where the ECC circuit 26 passes the ECC processing (S403_Yes), the CPU 22 checks whether a fail bit count (FBC) is less than a preset determination value. In a case where the fail bit count is less than the determination value (S404_Yes), the CPU 22 ends the patrol processing.

In a case where the ECC circuit 26 fails the ECC processing (S403_No) or in a case where the fail bit count FBC is equal to or larger than the preset determination value (S404_No), the CPU 22 causes the memory chip CP to execute the bit count read operation of the anchor as in step S304 (S405).

In a case where the bit count read operation ends in the memory chip CP, the read voltage correction circuit 27 acquires a bit count (bit count data BC) of read data from the memory chip CP as in step S305 (S406). In other words, the read voltage correction circuit 27 acquires a count value for each read voltage from the memory chip CP.

Next, the read voltage correction circuit 27 acquires expected values of the number of bits (a count value of write data for each state) by referring to the bit count management table 241 as in step S306 (S407).

The read voltage correction circuit 27 estimates a read position (shift amount) for each read voltage based on the bit count data BC (the count value for each read voltage) and the expected value of the number of bits (the count value of the write data for each state) as in step S307 (S408).

The read voltage correction circuit 27 updates the read position based on a result of the estimation (S409). That is, the read voltage correction circuit 27 updates the information concerning the shift amount in the bit count management table 241.

### 1.8 Effects according to Present Embodiment

According to the configuration according to the present embodiment, reliability of the memory system can be improved. This effect will be described in detail.

For example, in a case where a shift amount of a read voltage is corrected, there is a method of calculating the shift amount based on read data before ECC processing and read data that has passed the ECC processing (decoding process). However, according to this method, the shift amount cannot be calculated unless the ECC processing is passed.

On the other hand, according to the configuration according to the present embodiment, the memory system 3 can acquire, as an expected value, a count value of the number of bits of write data for each state in write operation. Furthermore, the memory system 3 can acquire a count value of the number of bits of read data of each state (a count value of the number of bits for each read voltage) in read operation. The memory system 3 can calculate a shift amount of the read voltage based on a difference between the count value of the read data and the count value of the write data. This makes it possible to calculate the shift amount of the read voltage even in a case where the number of fail bits of the read data exceeds the number of fail bits that can be ECC-processed. It is therefore possible to improve reliability of the memory system 3.

Furthermore, according to the configuration according to the present embodiment, even in a case where the ECC processing fails, the shift amount is calculated by one bit count read operation. For example, it is not necessary to execute the read operation a plurality of times while shifting the read voltage unlike soft bit decoding processing or tracking read. This makes it possible to suppress an increase in processing time of the read operation. It is therefore possible to improve processing performance of the memory system 3.

### 2. SECOND EMBODIMENT

Next, a second embodiment will be described. In the second embodiment, a case where a memory chip CP acquires a count value of write data for each state will be described. Differences from the first embodiment will be mainly described below.

### 2.1 Overall Flow of Write Operation

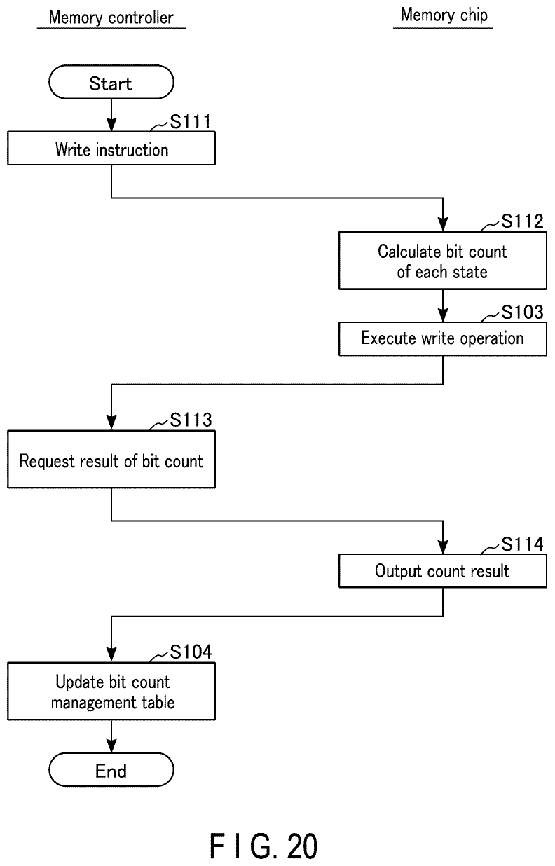

First, an example of overall flow of write operation will be described with reference to FIG. 20. FIG. 20 is a flowchart illustrating an example of the overall flow of the write operation. Note that FIG. 20 illustrates a case where all write data is a target of counting of the number of bits.

As illustrated in FIG. 20, upon receipt of a write request from the host 2, the ECC circuit 26 generates write data. Then, the CPU 22 instructs the non-volatile memory 10 to execute write operation (S111). That is, the memory controller 20 transmits a command set instructing execution of the write operation to the memory chip CP.

In a case where the write data is stored in the latch circuit of the sense amplifier, the counter 114 calculates a bit count of the write data of each state (S112). The counter 114 stores a result of the count in a bit count register 104.

The sequencer 108 executes the write operation based on the command set of the write operation (S103). Note that step S112 and step S103 may be executed in any order. Step S112 and step S103 may be executed in parallel or step S112 may be executed after step S103.

In a case where the write operation (bit count) in the memory chip CP is ended, the CPU 22 requests a result of the bit count (bit count data BC) from the memory chip CP (S113).

The memory chip CP outputs the result of the bit count (bit count data BC) stored in the bit count register 104 to the memory controller 20 (S114).

The read voltage correction circuit 27 updates the bit count management table 241 (S104). More specifically, the read voltage correction circuit 27 stores a result of the bit count for each state as an expected value of the number of bits in the bit count management table 241.

### 2.2 Flow of Write Data in Memory Chip

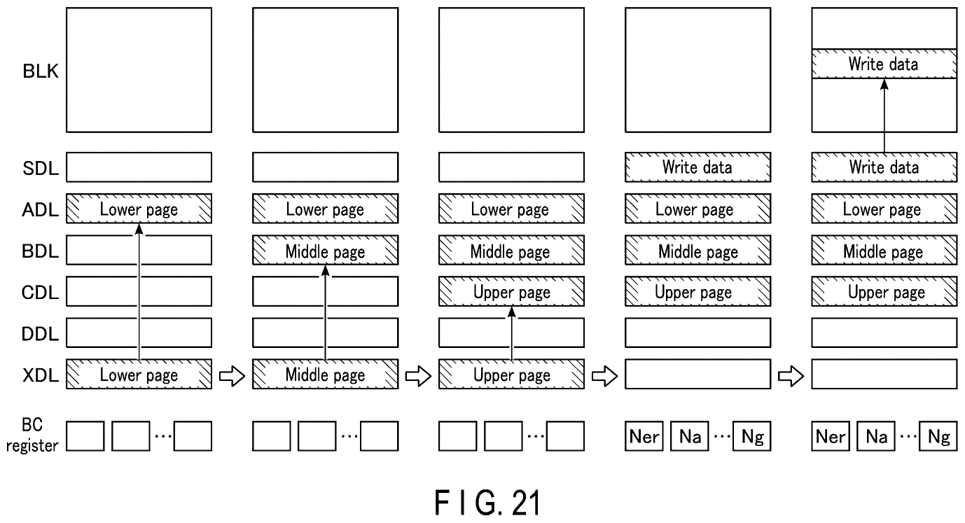

Next, an example of flow of write data in the memory chip CP will be described with reference to FIG. 21. FIG. 21 illustrates an example of flow of write data in the memory chip CP. FIG. 21 illustrates a case where lower page data, middle page data, and upper page data are collectively written.

As illustrated in FIG. 21, first, the lower page data is input to the latch circuit XDL of the data register 115. The lower page data of the latch circuit XDL is, for example, transferred to the latch circuit ADL of the sense amplifier 113.

Next, the middle page data is input to the latch circuit XDL of the data register 115. The middle page data of the latch circuit XDL is, for example, transferred to the latch circuit BDL of the sense amplifier 113.

Next, the upper page data is input to the latch circuit XDL of the data register 115. The upper page data of the latch circuit XDL is, for example, transferred to the latch circuit CDL of the sense amplifier 113.

The counter 114 calculates a count value of each state by referring to the latch circuits ADL, BDL, and CDL. The counter 114 stores count values Ner, Na, . . . , and Ng in the bit count register 104.

A sense circuit SA calculates data to be written to a cell unit CU selected as a write target by executing computation using the lower page data, the middle page data, and the upper page data, and stores the data in a latch circuit SDL.

Next, the sense circuit SA writes the write data of the latch circuit SDL to the cell unit CU.

### 2.3 Command Sequence of Write Operation

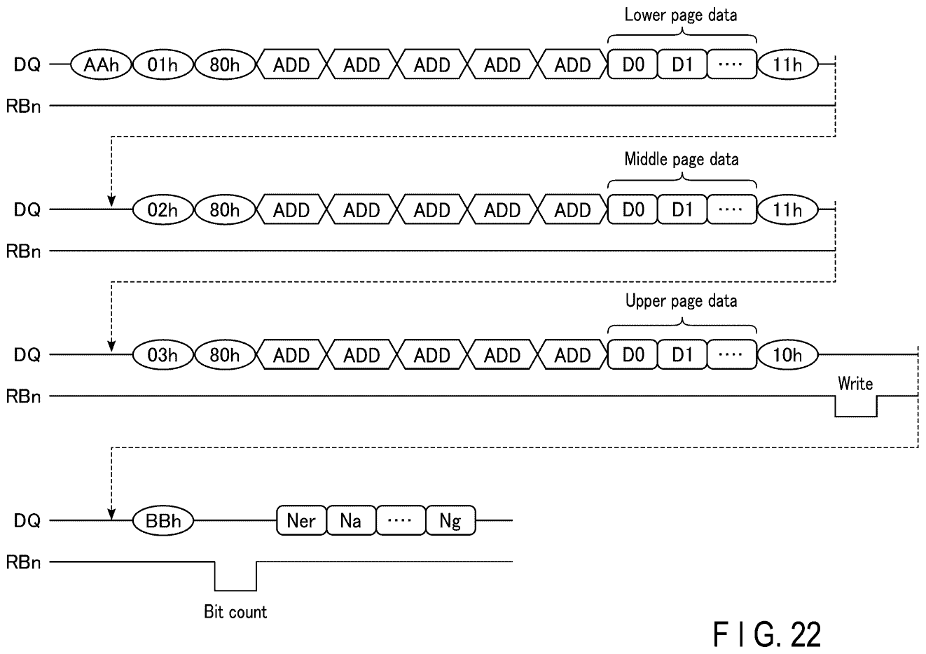

Next, an example of a command sequence of the write operation will be described with reference to FIG. 22. FIG. 22 is a timing chart illustrating an example of a command sequence of the write operation.

As illustrated in FIG. 22, first, the memory controller 20 transmits a prefix command “AAh” to the memory chip CP. The command “AAh” is a command giving a notification of count of the number of bits of write data for each state. Next, similarly to the description using FIG. 11 of the first embodiment, the memory controller 20 sequentially transmits commands “01h” and “80h”, 5 cycles of an address “ADD”, the lower page data, and a command “11h” to the memory chip CP. Upon receipt of the command “11h”, the sequencer 108 stores the lower page data, for example, in the latch circuit ADL.

Next, similarly to the description using FIG. 11 of the first embodiment, the memory controller 20 sequentially transmits commands “02h” and “80h”, 5 cycles of the address “ADD”, the middle page data, and the command “11h” to the memory chip CP. Upon receipt of the command “11h”, the sequencer 108 stores the middle page data, for example, in the latch circuit BDL.

Next, similarly to the description using FIG. 11 of the first embodiment, the memory controller 20 sequentially transmits commands “03h” and “80h”, 5 cycles of the address “ADD”, the upper page data, and a command “10h” to the memory chip CP. The command “10h” is a command instructing execution of the write operation. Upon receipt of the command “10h”, the sequencer 108 sets the ready/busy signal RBn to the “L” level. Then, after storing the upper page data, for example, in the latch circuit CDL, the sequencer 108 executes the write operation based on the lower page data, the middle page data, and the upper page data.

In a case where the write operation is ended, the sequencer 108 sets the ready/busy signal RBn to the “H” level.

After confirming that the ready/busy signal RBn is at the “H” level, the memory controller 20 transmits a command “BBh” to the memory chip CP. The command “BBh” is a command requesting output of the bit count data BC from the memory chip CP. For example, upon receipt of the command “BBh”, the sequencer 108 sets the ready/busy signal RBn to the “L” level and calculates a bit count for each state. In a case where the counting ends, the sequencer 108 sets the ready/busy signal to the “H” level.

After confirming that the ready/busy signal RBn is at the “H” level, the CPU 22 sequentially reads the bit count data BC, that is, the count values Ner, Na, . . . , and Ng from the bit count register 104 of the memory chip CP. The read voltage correction circuit 27 updates the bit count management table 241.

### 2.4 Effects According to Present Embodiment

According to the configuration according to the present embodiment, similar effects to those of the first embodiment can be obtained.

Furthermore, according to the configuration according to the present embodiment, the memory chip CP can count the number of bits of write data for each state. Therefore, counting of write data in the memory controller 20 can be omitted, and a load of the memory controller 20 can be reduced.

### 3. THIRD EMBODIMENT

Next, a third embodiment will be described. In the third embodiment, two examples of a command sequence of a bit count read operation different from that of the first embodiment will be described. Differences from the first embodiment will be mainly described below.

### 3.1 First Example

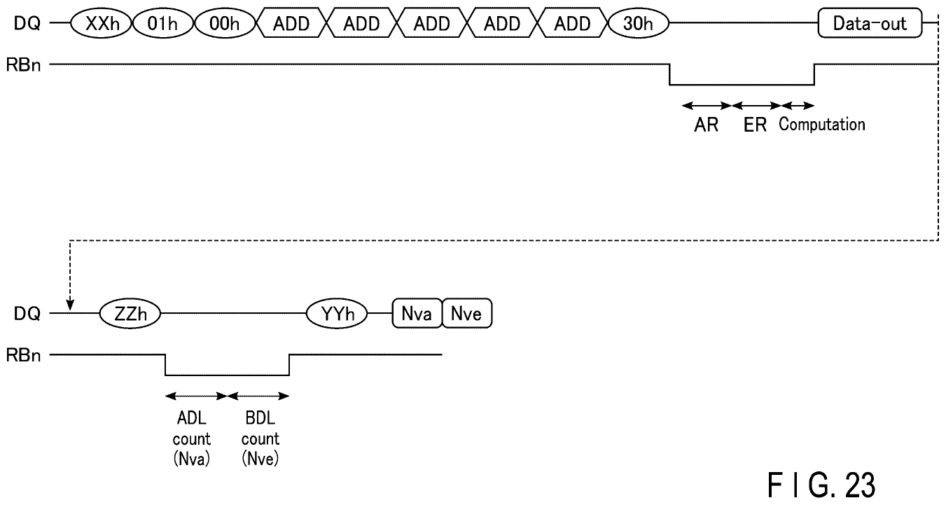

First, a command sequence of a bit count read operation according to a first example will be described with reference to FIG. 23. FIG. 23 is a timing chart illustrating a first example of a command sequence of a bit count read operation of lower page data.

As illustrated in FIG. 23, similarly to the description of FIG. 17 of the first embodiment, the memory controller 20 sequentially transmits a prefix command “XXh”, commands “01h” and “00h”, 5 cycles of an address “ADD”, and a command “30h” to the memory chip CP.

Upon receipt of the command “30h”, the sequencer 108 sets the ready/busy signal RBn to the “L” level. In this example, AR read operation, ER read operation, and EXOR operation are sequentially executed, and at this time, calculation of a bit count by the counter 114 is not executed.

In a case where the EXOR operation is ended and lower page data is stored in the latch circuit XDL, the sequencer 108 sets the ready/busy signal RBn to the “H” level.

After confirming that the ready/busy signal RBn has changed from the “L” level to the “H” level, the memory controller 20 causes the memory chip CP to output read data (Data-out).

In a case where the output of the read data is ended, the memory controller 20 transmits a command “ZZh” to the memory chip CP. The command “ZZh” is a command instructing calculation of a bit count.

Upon receipt of the command “ZZh”, the sequencer 108 sets the ready/busy signal RBn to the “L” level. The counter 114 executes, for example, calculation of a bit count concerning the lower page data. More specifically, for example, the counter 114 executes counting of AR data stored in the latch circuit ADL (calculation of a count value Nva) and counting of ER data stored in the latch circuit BDL (calculation of a count value Nve).

In a case where the calculation of the bit count is ended, the sequencer 108 sets the ready/busy signal RBn to the “H” level.

Next, after confirming that the ready/busy signal RBn is at the “H” level, the memory controller 20 transmits a command “YYh” to the memory chip CP. Next, the memory controller 20 reads the count values Nva and Nve as bit count data BC from the memory chip CP.

### 3.2 Second Example

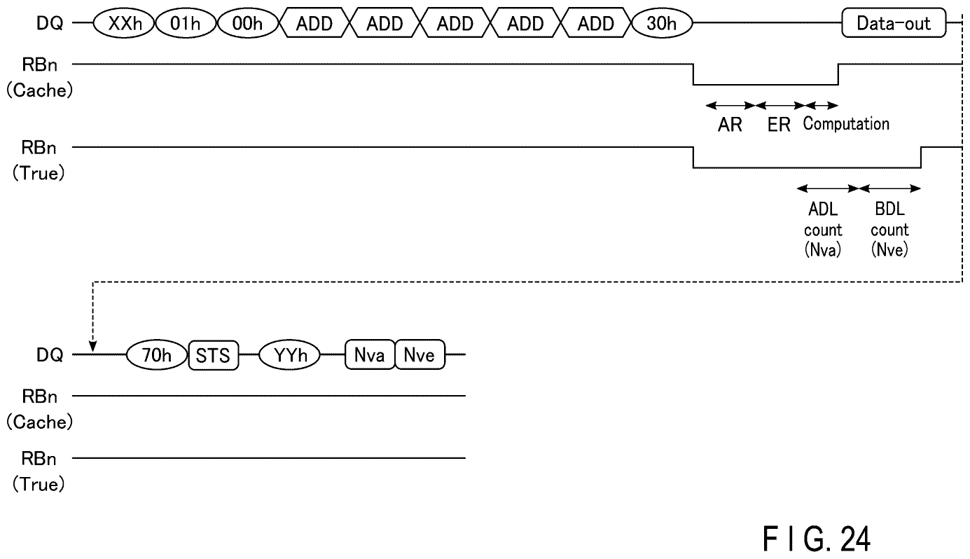

Next, a command sequence of a bit count read operation according to a second example will be described with reference to FIG. 24. FIG. 24 is a timing chart illustrating a second example of a command sequence of a bit count read operation of lower page data.

As illustrated in FIG. 24, in the present example, there are two ready/busy signals, RBn (Cache) and RBn (True). For example, the ready/busy signal RBn (Cache) is information identical to the ready/busy signal RBn transmitted from the ready/busy circuit 103 to the memory controller 20 described with reference to FIG. 2. The ready/busy signal RBn (Cache) is a signal indicating whether or not the memory controller 20 can access the latch circuit XDL. The ready/busy signal RBn (True) is a signal indicating whether or not the memory chip CP is operating. For example, the ready/busy signals RBn (Cache) and RBn (True) are included in status information STS. The memory controller 20 can confirm the ready/busy signals RBn (Cache) and RBn (True) by reading the status information STS.

First, similarly to the description of FIG. 17 of the first embodiment, the memory controller 20 sequentially transmits a prefix command “XXh”, commands “01h” and “00h”, 5 cycles of an address “ADD”, and a command “30h” to the memory chip CP.

Upon receipt of the command “30h”, the sequencer 108 sets the ready/busy signals RBn (Cache) and RBn (True) to the “L” level. Next, the sequencer 108 sequentially executes AR read operation, ER read operation, and EXOR operation. In parallel with these operations, the counter 114 executes calculation of a bit count of lower page data. More specifically, for example, the counter 114 executes counting of AR data stored in a latch circuit ADL (calculation of a count value Nva) and counting of ER data stored in a latch circuit BDL (calculation of a count value Nve).

In a case where the EXOR operation is ended and lower page data is stored in the latch circuit XDL, the sequencer 108 sets the ready/busy signal RBn (Cache) to the “H” level. At this time, the calculation of the bit count by the counter 114 has not been ended, and therefore the ready/busy signal RBn (True) maintains the “L” level.

After confirming that the ready/busy signal RBn (Cache) is at the “H” level, the memory controller 20 causes the memory chip CP to output read data (Data-out). For example, in a case where the calculation of the bit count by the counter 114 ends during the data output, the sequencer 108 sets the ready/busy signal RBn (True) to the “H” level.

In a case where the output of the data is ended, the memory controller 20 transmits a command “70h” to the memory chip CP. The command “70h” is a command instructing output of the status information STS.

The memory controller 20 reads the status information STS from the memory chip CP, and after confirming that the ready/busy signal RBn (True) is at the “H” level, transmits a command “YYh” to the memory chip CP. Next, the memory controller 20 reads the count values Nva and Nve as bit count data BC from the memory chip CP.

### 3.3 Effects according to Present Embodiment

According to the configuration according to the present embodiment, similar effects to those of the first embodiment can be obtained.

Furthermore, according to the configuration according to the present embodiment, it is possible to suppress an increase in processing time from start of read operation to read data output in the bit count read operation.

Note that the present embodiment may be combined with the second embodiment.

### 4. FOURTH EMBODIMENT

Next, a fourth embodiment will be described. In the fourth embodiment, three examples of flow of patrol read different from that of the first embodiment will be described. Differences from the first embodiment will be mainly described below.

### 4.1 First Example

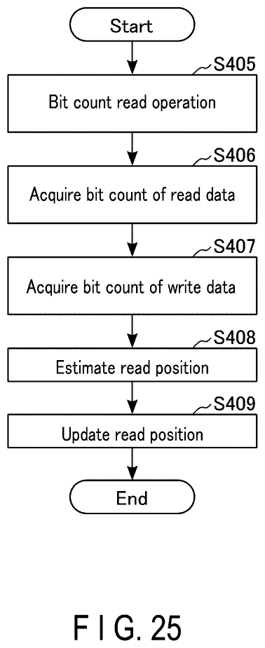

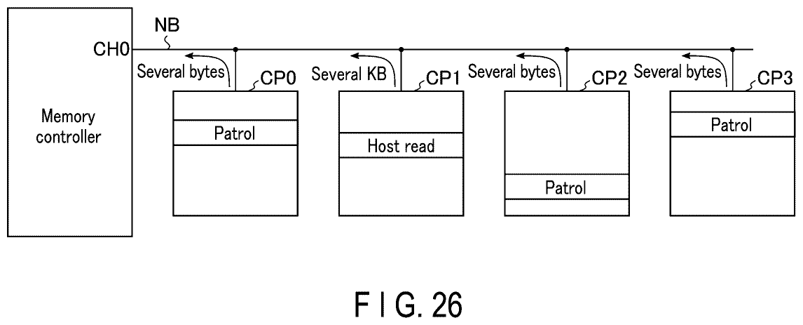

First, a first example of patrol read to which a bit count read operation is applied will be described with reference to FIGS. 25 and 26. FIG. 25 is a flowchart in which a bit count read operation is applied to patrol read according to a first example. FIG. 26 is a conceptual diagram illustrating data output from a memory chip CP to a memory controller 20 in patrol read or host read.

As illustrated in FIG. 25, in this example, output of read data from the memory chip CP to the memory controller 20 and ECC processing of the read data in the memory controller 20 are omitted. That is, steps S401 to S404 of the patrol read described with reference to FIG. 19 of the first embodiment are omitted.

First, a CPU 22 causes the memory chip CP to execute the bit count read operation of an anchor (S405).

In a case where the bit count read operation ends, the read voltage correction circuit 27 acquires a bit count (bit count data BC) of read data from the memory chip CP (S406). At this time, the read data is not output from the memory chip CP.

Next, the read voltage correction circuit 27 acquires expected values of the number of bits (a count value of write data for each state) by referring to the bit count management table 241 (S407).

The read voltage correction circuit 27 estimates a read position (shift amount) for each read voltage based on the bit count data BC (the count value for each read voltage) and the expected value of the number of bits (the count value of the write data for each state) (S408).

The read voltage correction circuit 27 updates the read position based on a result of the estimation (S409). That is, the read voltage correction circuit 27 updates the information concerning the shift amount in the bit count management table 241.

Next, a difference between a data transfer amount in the patrol read to which the present example is applied and a data transfer amount in the host read will be described with reference to FIG. 26.

As illustrated in FIG. 26, for example, four memory chips CP0 to CP3 are coupled to a channel CH0 of the memory controller 20 via a NAND bus NB. The patrol read is executed in the memory chips CP0, CP2, and CP3, and the host read is executed in the memory chip CP1.

For example, a data amount of the read data is approximately several KB. On the other hand, a data amount of the bit count data BC is approximately several bytes since the bit count data BC is information on a count value.

In a case where the host read ends in the memory chip CP1, read data (several KB) is transmitted from the memory chip CP1 to the memory controller 20 via the NAND bus NB.

In this example, in the patrol read, output of the read data is not executed. Therefore, in a case where the patrol read ends in the memory chips CP0, CP2, and CP3, the bit count data BC (several bytes) is transmitted from the memory chips CP to the memory controller 20 via the NAND bus NB. In this example, the data transfer amount by the patrol read can be reduced to several bytes, and therefore a possibility of data collision in the NAND bus can be reduced during data transfer from the memory chips CP to the memory controller 20. Therefore, an increase in tail latency of the read operation can be suppressed.

### 4.2 Second Example

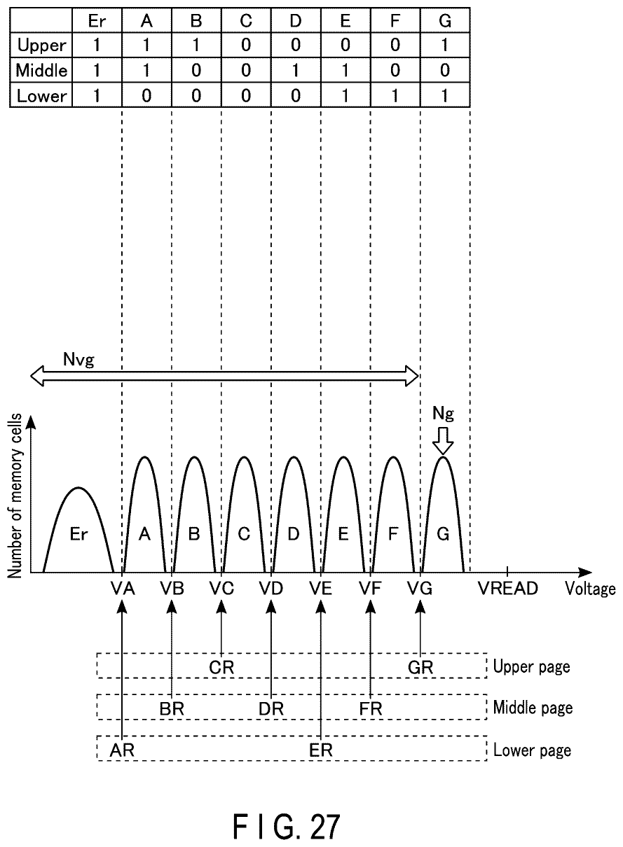

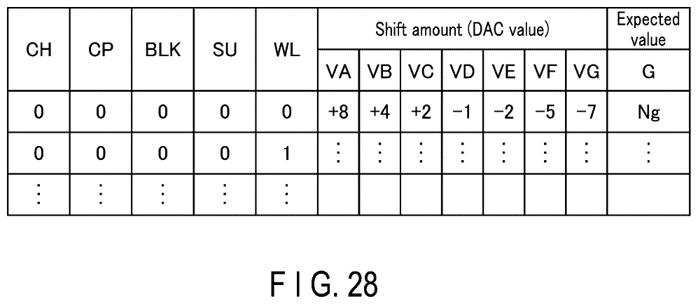

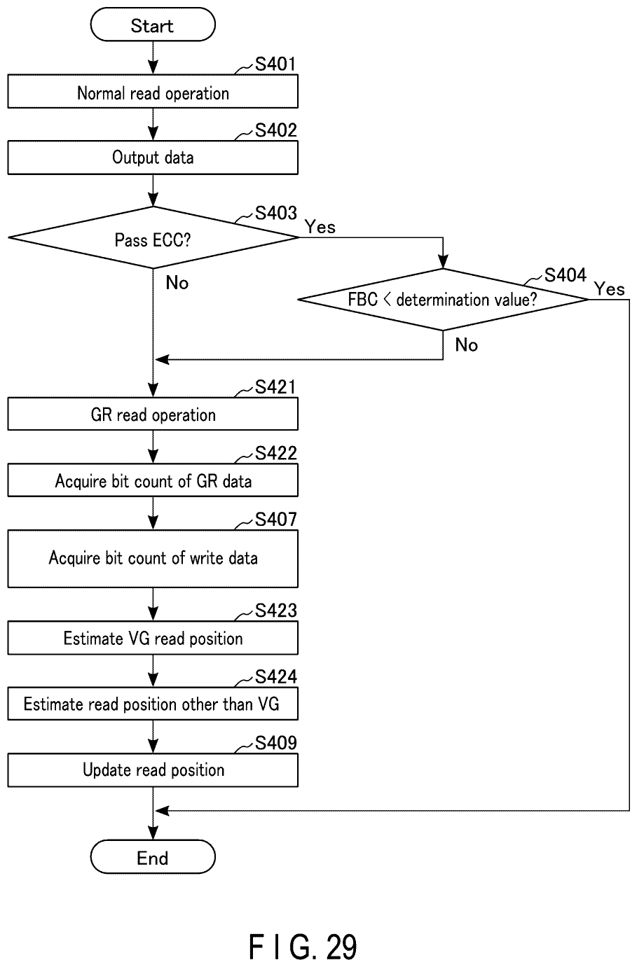

Next, a second example of patrol read to which a bit count read operation is applied will be described with reference to FIGS. 27 to 29. FIG. 27 illustrates a relationship among a threshold voltage distribution, data allocation, and a count value of the number of bits in a case where memory cell transistors MC are TLCs that can store 3-bit (8-value) data. FIG. 28 illustrates an example of a bit count management table 241. FIG. 29 is a flowchart in which a bit count read operation is applied to patrol read according to a second example.

For example, amounts of data retention in respective states have a correlation. Accordingly, the amount of data retention in a lower state can be estimated from the amount of data retention in the uppermost “G” state having the largest amount of data retention. In other words, since shift amounts of the read voltages VA to VG are correlated with each other, the shift amounts of the other read voltages VA to VF can be estimated from the shift amount of the read voltage VG (GR read operation). In the present example, a case where the shift amounts of the other read voltages VA to VF are estimated from the shift amount of the read voltage VG (GR read operation) will be described.

First, calculation of a count value of the number of bits will be described with reference to FIG. 27.

As illustrated in FIG. 27, in a case where the memory cell transistors MC are TLCs, read voltages and data allocation corresponding to respective states are similar to the description of FIG. 5 of the first embodiment.

In this example, in write operation, a count value Ng of the memory cell transistors MC included in the “G” state of write data is calculated, and the other count values Ner and Na to Nf described in the first embodiment are not calculated. The read voltage correction circuit 27 calculates a count value (the number of memory cell transistors MC included in the cell unit CU-Ng) by using the count value Ng. The count value (the number of memory cell transistors MC included in the cell unit CU-Ng) is equal to the count value (Ner+Na+Nb+Nc+Nd+Ne+Nf). Therefore, the read voltage correction circuit 27 can calculate a difference Δ (=Nvg−(Ner+Na+Nb+Nc+Nd+Ne+Nf)) corresponding to the read voltage VG.

Furthermore, in the present example, in the GR read operation, the count value Nvg of the memory cell transistors MC whose threshold voltage is lower than the voltage VG is calculated. In the AR to FR read operations, the count values Nva to Nvf are not calculated.

As illustrated in FIG. 28, in the bit count management table 241, the count value Ng is stored as an expected value of the number of bits of the “G” state. Unlike the description using FIG. 6 of the first embodiment, expected values of the number of bits of the “Er” and “A” to “F” states are not stored in the bit count management table 241.

Next, a flowchart of the patrol read in the present example will be described with reference to FIG. 29.

As illustrated in FIG. 29, steps S401 to S404 are executed similarly to the description of FIG. 19 of the first embodiment.

In a case where an ECC circuit 26 fails ECC processing (S403_No) or in a case where a fail bit count FBC is equal to or larger than a preset determination value (S404_No), the CPU 22 causes the memory chip CP to execute the GR read operation (the bit count read operation using the read voltage VG) of the anchor (S421). The sequencer 108 reads GR data from the anchor. The counter 114 calculates a bit count of the GR data, and stores a result of the bit count (the count value Nvg) in a bit count register 104.

In a case where the GR read operation is ended in the memory chip CP, the read voltage correction circuit 27 acquires the bit count (the count value Nvg) of the GR data from the memory chip CP (S422).

Next, the read voltage correction circuit 27 acquires an expected value of the number of bits (a count value of write data of “G” state) by referring to the bit count management table 241 (S407).

The read voltage correction circuit 27 estimates a read position (shift amount) of the read voltage VG based on the count value Nvg and the expected value of the number of bits (S423).

The read voltage correction circuit 27 estimates read positions (shift amounts) of the read voltages other than the read voltage VG based on a result of the estimation of the read position (shift amount) of the read voltage VG (S424). That is, the read voltage correction circuit 27 estimates the read positions (shift amounts) of the read voltages VA to VF.

The read voltage correction circuit 27 updates the read positions based on a result of the estimation of the read positions (shift amounts) of the read voltages VA to VG (S409). That is, the read voltage correction circuit 27 updates the information concerning the shift amount in the bit count management table 241.

### 4.3 Third Example

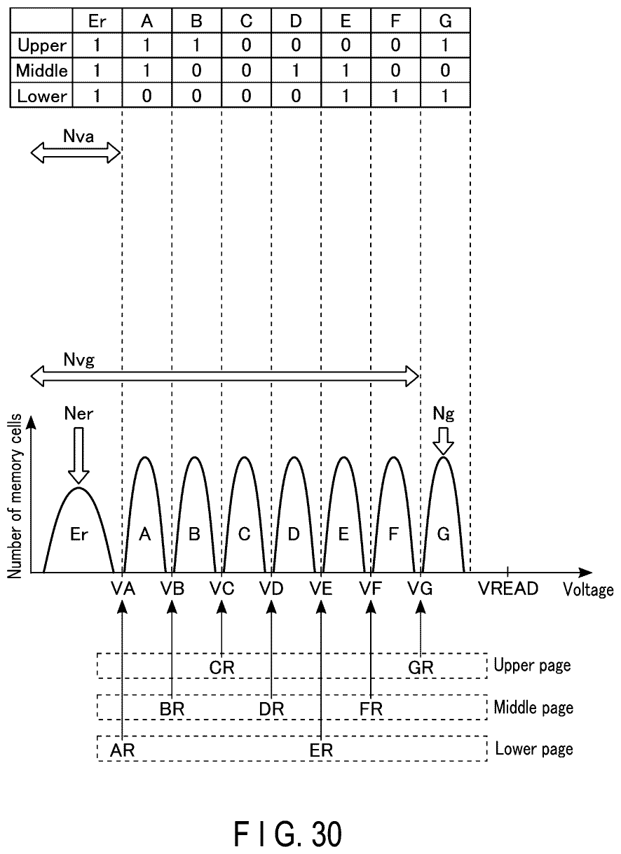

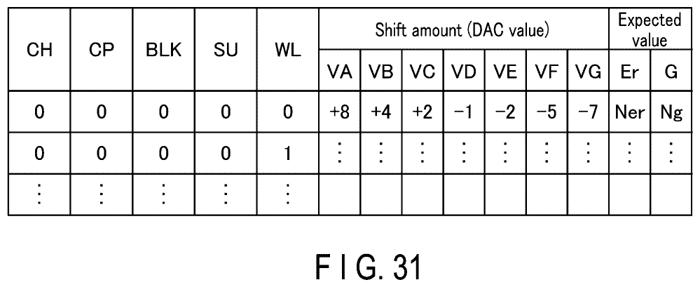

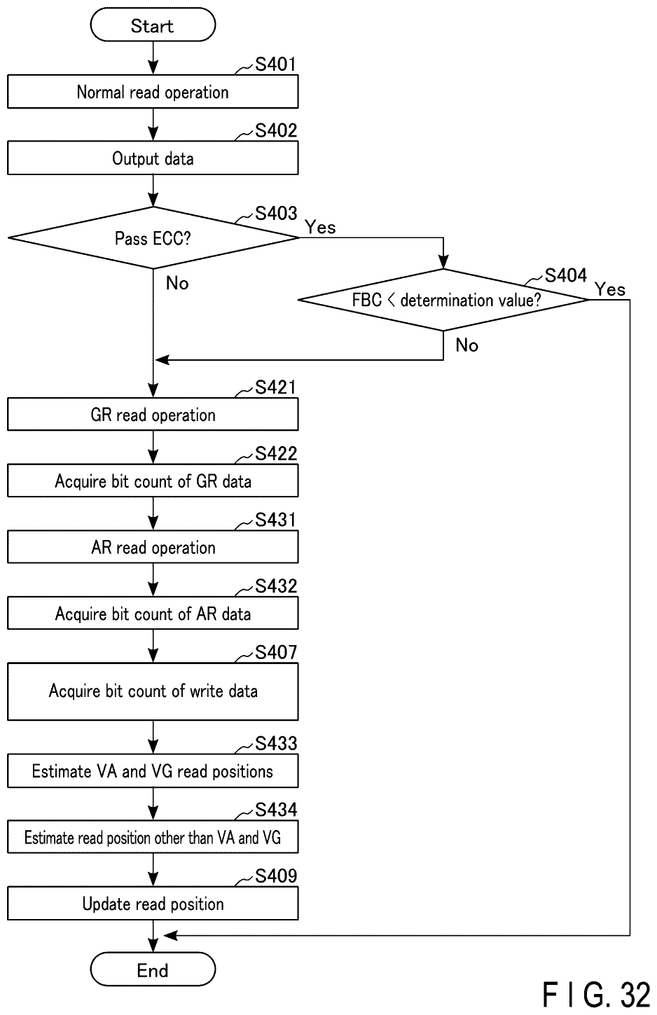

Next, a third example of patrol read to which a bit count read operation is applied will be described with reference to FIGS. 30 to 32. FIG. 30 illustrates a relationship among a threshold voltage distribution, data allocation, and a count value of the number of bits in a case where memory cell transistors MC are TLCs that can store 3-bit (8-value) data. FIG. 31 illustrates an example of a bit count management table 241. FIG. 32 is a flowchart in which a bit count read operation is applied to patrol read according to a third example.

Although the case where the shift amounts of the read voltages VA to VF are estimated from the shift amount of the read voltage VG has been described in the second example of the present embodiment, a fluctuation of the threshold voltage caused by read disturb in the lowermost “Er” state is larger than that in other states. Therefore, in some cases, the read voltage VA cannot be estimated from the shift amount of the read voltage VG due to the influence of the read disturb. Therefore, in the present example, a case where the shift amounts of the read voltages VB to VF are estimated from the shift amounts of the read voltages VA and VG will be described.

First, calculation of a count value of the number of bits will be described with reference to FIG. 30.

As illustrated in FIG. 30, the count values Ner and Ng are calculated and the other count values Na to Nf are not calculated in write operation, unlike the second example of the present embodiment.

Furthermore, in the present example, the count values Nva and Nvg are calculated in the AR and GR read operations, respectively. The count values Nvb to Nvf are not calculated in the BR to FR read operations.

As illustrated in FIG. 31, the count values Ner and Ng are stored in the bit count management table 241 as expected values of the number of bits of the “Er” and “G” states, respectively. Expected values of the number of bits of the “A” to “F” states are not stored in the bit count management table 241.

Next, a flowchart of the patrol read in the present example will be described with reference to FIG. 32.

As illustrated in FIG. 32, steps S401 to S404, S421, and S422 are executed similarly to the description of FIG. 29.

After the read voltage correction circuit 27 acquires the bit count (the count value Nvg) of GR data, the CPU 22 causes the memory chip CP to execute the AR read operation (the bit count read operation using the read voltage VA) of the anchor (S431). The sequencer 108 reads AR data from the anchor. The counter 114 calculates a bit count of the AR data, and stores a result of the bit count (the count value Nva) in the bit count register 104.

In a case where the AR read operation is ended in the memory chip CP, the read voltage correction circuit 27 acquires the bit count (the count value Nva) of the AR data from the memory chip CP (S432). Note that the read voltage correction circuit 27 may collectively execute steps S422 and S432. That is, the read voltage correction circuit 27 may collectively acquire the count values Nva and Nvg from the memory chip CP.

Next, the read voltage correction circuit 27 acquires expected values of the number of bits (count values of write data of “A” state and “G” state) by referring to the bit count management table 241 (S407).

The read voltage correction circuit 27 estimates the read positions (shift amounts) of the read voltages VA and VG based on the count values Nva and Nvg and the expected values of the number of bits (S433).

The read voltage correction circuit 27 estimates read positions (shift amounts) of the read voltages other than the read voltage VA and VG based on a result of the estimation of the read positions (shift amounts) of the read voltage VA and VG (S434). That is, the read voltage correction circuit 27 estimates the read positions (shift amounts) of the read voltages VB to VF.

The read voltage correction circuit 27 updates the read positions based on a result of the estimation of the read positions (shift amounts) of the read voltages VA to VG (S409). That is, the read voltage correction circuit 27 updates the information concerning the shift amount in the bit count management table 241.

### 4.4 Effects according to Present Embodiment

According to the configuration according to the present embodiment, similar effects to those of the first embodiment can be obtained.

Furthermore, in the configuration according to the first example of the present embodiment, output of read data from the memory chip CP to the memory controller 20 and the ECC processing can be omitted in the patrol read. Accordingly, the data transfer amount from the memory chip CP to the memory controller 20 can be reduced, and the possibility of data collision in the NAND bus can be reduced. Therefore, an increase in tail latency in the read operation can be suppressed. It is therefore possible to improve processing performance of the memory system 3.

Furthermore, according to the configurations according to the second example and the third example of the present embodiment, shift amounts of other read voltages can be estimated from a shift amount of one or some read voltages. More specifically, according to the configuration according to the second example of the present embodiment, in the case of TLCs, the shift amounts of the read voltages VA to VF can be estimated from the shift amount of the read voltage VG. Alternatively, according to the configuration according to the third example of the present embodiment, the shift amounts of the read voltages VB to VF can be estimated from the shift amounts of the read voltages VA and VG. Therefore, the bit count management table 241 need just store a count value (for example, Ng, or Na and Ng) of one or some states as the expected value of the number of bits. As a result, a memory capacity of a RAM 24 can be reduced. Similarly, in the memory chip CP, the bit count register 104 only needs to be able to store a count value (for example, Ng, or Na and Vg) corresponding to one or some read voltages. As a result, a memory capacity of the bit count register 104 can be reduced.

Furthermore, according to the configurations according to the second example and the third example of the present embodiment, it is possible to reduce the number of read operations necessary for calculating the shift amounts in the patrol read. As a result, the processing time of the patrol read can be shortened. It is therefore possible to improve processing performance of the memory system 3.

Although the case of the patrol read has been described in the second example and the third example, these examples can also be applied to the host read.

### 5. MODIFICATIONS AND OTHERS

A memory system according to the above embodiments includes a memory chip (CP) including a plurality of memory cells (MC) each of which is capable of storing data corresponding to one of a plurality of states (“Er” to “G”) and a memory controller (20). The memory controller is configured to control a write operation and a read operation performed on the memory cells and calculate a shift amount of a read voltage in the read operation based on at least one of a plurality of first count values (Ner, Na, Nb, Nc, Nd, Ne, and Nf) of write data corresponding to the plurality of states in the write operation and a second count value (Nva, Nvb, Nvc, Nvd, Nve, Nvf, or Nvg) corresponding to the read voltage.

The memory systems according to the above embodiments can improve reliability with the configurations according to the above embodiments.

Note that the present invention is not limited to the above embodiments, and various modifications can be applied.

Furthermore, the “coupling” in the above embodiments also includes a state where elements are indirectly coupled with another element such as a transistor or a resistor interposed therebetween.

For example, although the case where the counter 114 calculates a count value of memory cell transistors MC whose threshold voltage is lower than the read voltage in the AR to GR read operations has been described in the above embodiments, the present invention is not limited to this. The counter 114 may calculate a count value of memory cell transistors MC whose threshold voltage is equal to or higher than the read voltage.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a memory chip including a plurality of memory cells each of which is capable of storing data corresponding to one of a plurality of states; and
a memory controller configured to:
control a write operation and a read operation performed on the memory cells; and
calculate a shift amount of a read voltage in the read operation based on at least one of a plurality of first count values of write data corresponding to the plurality of states in the write operation and a second count value corresponding to the read voltage.

2. The memory system according to claim 1, wherein
the memory controller is further configured to calculate the shift amount of the read voltage based on a difference between the second count value and a sum of one or more first count values corresponding to a state having a threshold voltage distribution lower than the read voltage among the first count values.

3. The memory system according to claim 2, wherein
in a case where the difference is a negative value, the shift amount is set to a positive value, and
in a case where the difference is a positive value, the shift amount is set to a negative value.

4. The memory system according to claim 1, wherein
the memory chip further includes:
a sense amplifier coupled to the memory cells; and
a counter coupled to the sense amplifier, and
the counter is configured to count the number of memory cells having a threshold voltage lower than the read voltage among the memory cells in the read operation.

5. The memory system according to claim 4, wherein
the counter is configured to count the number of memory cells having data of either “1” or “0”, the data being read using the read voltage.

6. The memory system according to claim 1, wherein
the memory controller is further configured to calculate the shift amount in a case where an error correction processing of read data fails in the read operation.

7. The memory system according to claim 1, wherein
the memory controller is further configured to calculate the shift amount in a case where an error correction processing of read data fails in the read operation and the number of fail bits is equal to or larger than a determination value.

8. The memory system according to claim 1, wherein
the memory controller is further configured to count the first count values in the write operation.

9. The memory system according to claim 1, wherein
the memory chip is further configured to count the first count values in the write operation.

10. The memory system according to claim 1, wherein
the memory chip outputs read data to the memory controller after reading of data from the plurality of memory cells and calculation of the second count value are ended in the read operation.

11. The memory system according to claim 1, wherein
the memory chip calculates the second count value after reading of data from the plurality of memory cells and output of read data to the memory controller are ended in the read operation.

12. The memory system according to claim 1, wherein
the memory controller is further configured to acquire the second count value without acquiring read data from the plurality of memory chip in the read operation.

13. The memory system according to claim 1, wherein
the memory controller is further configured to determine a shift amount of a read voltage corresponding to a second state different from a first state among the plurality of states based on a shift amount of a read voltage corresponding to the first state, the first state having a highest corresponding threshold voltage distribution among the plurality of states.

14. The memory system according to claim 1, wherein
the memory controller is further configured to determine a shift amount of a read voltage corresponding to a third state different from a first state and a second state among the plurality of states based on a shift amount of a read voltage corresponding to the first state and a shift amount of a read voltage corresponding to the second state, the first state having a highest corresponding threshold voltage distribution among the plurality of states and the second state having a lowest corresponding threshold voltage distribution among the plurality of states.

15. The memory system according to claim 1, wherein
the plurality of states include:
a first state having a lowest threshold voltage distribution,
one or more second states adjacent to the first state and having a threshold voltage distribution higher than that of the first state and lower than the read voltage, and
a third state adjacent to the second states and having a threshold voltage distribution higher than that of the one or more second states and higher than the read voltage, and
the memory controller is further configured to calculate the shift amount of the read voltage based on a difference between the second count value and a sum of a third count value corresponding to the first state among the first count values and one or more fourth count values corresponding to the one or more second states among the first count values.

16. A method for controlling a non-volatile memory including a plurality of memory cells each capable of storing data corresponding to one of a plurality of states, the method comprising:
controlling a write operation and a read operation performed on the memory cells;
acquiring a plurality of first count values of write data respectively corresponding to the plurality of states in the write operation;
acquiring a second count value corresponding to a read voltage in the read operation; and
calculating a shift amount of the read voltage based on at least one of the first count values and the second count value.

17. The method according to claim 16, wherein
the shift amount of the read voltage is calculated based on a difference between the second count value and a sum of one or more first count values corresponding to a state having a threshold voltage distribution lower than the read voltage among the first count values.

18. The method according to claim 17, wherein
in a case where the difference is a negative value, the shift amount is set to a positive value, and
in a case where the difference is a positive value, the shift amount is set to a negative value.

19. The method according to claim 16, wherein
the acquiring the second count value includes counting the number of memory cells having a threshold voltage lower than the read voltage.

20. The method according to claim 16, wherein
the shift amount of the read voltage is calculated in a case where an error correction processing of read data fails in the read operation.
